(19) United States
(12) Patent Application Publication
(10) Pub. No.: US 2026/0282629 A1
(43) Pub. Date: Sep. 17, 2026

(54) DISPLAY PANEL, METHOD FOR MANUFACTURING DISPLAY PANEL, AND ELECTRONIC DEVICE

(71) Applicant: Tianma Advanced Display Technology Institute (Xiamen) Co., Ltd., Xiamen (CN)

(72) Inventors: Wenqi ZHOU, Xiamen (CN); Sitao HUO, Xiamen (CN); Tianyi WU, Xiamen (CN)

(73) Assignee: Tianma Advanced Display Technology Institute (Xiamen) Co., Ltd., Xiamen (CN)

(21) Appl. No.: 19/245,369

(22) Filed: Jun. 22, 2025

(30) Foreign Application Priority Data
Mar. 11, 2025 (CN) 202510285924.9

(51) Int. Cl. H10H 29/34; H10H 29/01

(52) U.S. Cl. CPC H10H 29/34; H10H 29/012

(57) ABSTRACT

The present application discloses a display panel, a method for manufacturing the display panel, and an electronic device. The display panel includes a display layer including a plurality of first light-emitting units which are arranged in an array; one of the plurality of first light-emitting units includes at least one first light-emitting element which emits light of a first color, wherein dominant wavelengths of the plurality of first light-emitting units satisfy: |D₁−D₂|>0.

### CROSS-REFERENCE TO RELATED APPLICATION

The present application claims priority to Chinese patent application No. 202510285924.9, entitled “DISPLAY PANEL, METHOD FOR MANUFACTURING DISPLAY PANEL, AND ELECTRONIC DEVICE”, filed on Mar. 11, 2025, the entire contents of which are incorporated here by reference.

### TECHNICAL FIELD

The present application relates to the technological field of display apparatus, and particularly, to a display panel, a method for manufacturing the display panel, and an electronic device.

### BACKGROUND

With the continuous development of science and technology, more and more electronic devices which have a display function have been widely used in people's daily life and work, have brought great convenience to people's daily life and work, and have become an indispensable tool for people nowadays. A main component of an electronic device for achieving the display function is the display panel.

The active display panel is a display panel that displays an image by self-luminescence of a light-emitting element. Compared with the passive display panel that needs backlight for image display, the active display panel has better performance in a plurality of aspects such as the contrast ratio, the color representation and the viewing angle range.

For the active display panel in which the transfer process is needed to form a light-emitting element array, there are display differences in light-emitting elements of the same light-emitting color, so that the display panel has the problem of non-uniform display.

### SUMMARY

In view of the above problem, the present application provides a display panel, a method for manufacturing the display panel, and an electronic device, so that the problem of non-uniform display of the display panel which is caused by the display difference in the light-emitting elements of the same color may be effectively solved. The specific solution is as follows.

In a first aspect, the present application provides a display panel which includes:
a display layer including a plurality of first light-emitting units which are arranged in an array; one of the plurality of first light-emitting units including at least one first light-emitting element which emits light of a first color, wherein
dominant wavelengths of the plurality of first light-emitting units satisfy:

$$\vert {D}_{1} - {D}_{2} \vert > 0 ,$$

where D₁ represents a first difference between the dominant wavelengths of the first light-emitting elements in two of the plurality of first light-emitting units which are adjacent to each other along a first direction, and the first direction includes at least one of a row direction or a column direction of the array where the plurality of first light-emitting units are located; and
D₂ represents a second difference between the dominant wavelengths of the first light-emitting elements in two of the plurality of first light-emitting units which are adjacent to each other along a second direction, an angle between the second direction and the first direction is greater than 0° and less than 90°.

In a second aspect, the present application provides an electronic device which includes the above display panel.

In a third aspect, the present application provides a method for manufacturing the display panel which includes:
manufacturing first device wafers;
testing the first device wafers to acquire wavelength distributions of a plurality of first light-emitting elements in the first device wafers;
determining the wavelength distributions based on dominant wavelengths of a plurality of test regions;
determining wafer complementary groups; and
welding and fixing the plurality of first light-emitting elements which are arranged in an array on an array base plate, and sourcing the plurality of first light-emitting elements which are welded and fixed on the array base plate to a same one of the wafer complementary groups; wherein
one of the first device wafers includes the plurality of first light-emitting elements which emit light of a first color,
one of the first device wafers includes the plurality of test regions, one of the plurality of test regions includes at least one of the plurality of first light-emitting elements,
one of the wafer complementary groups includes c of the first device wafers which have complementary wavelength distributions,
the array base plate has a plurality of first light-emitting units which are arranged in an array; and one of the plurality of first light-emitting units includes at least one first light-emitting element which emits light of a first color, wherein
dominant wavelengths of the plurality of first light-emitting units satisfy:

$$\vert {D}_{1} - {D}_{2} \vert > 0 ,$$

where D₁ represents a first difference between the dominant wavelengths of the first light-emitting elements in two of the plurality of first light-emitting units which are adjacent to each other along a first direction, and the first direction includes at least one of a row direction or a column direction of the array where the plurality of first light-emitting units are located; and
D₂ represents a second difference between the dominant wavelengths of the first light-emitting elements in two of the plurality of first light-emitting units which are adjacent to each other along a second direction, an angle between the second direction and the first direction is greater than 0° and less than 90°.

### BRIEF DESCRIPTION OF THE DRAWINGS

In order to illustrate technical solutions in embodiments of the present application or the related art more clearly, the drawings to be used in the description of the embodiments or the related art will be introduced briefly below. Obviously, the drawings described below are merely the embodiments of the present application, and for those of ordinary skill in the art, other drawings may be obtained based on the drawings without inventive effort.

The structures, proportions, sizes, and the like illustrated in the drawings of the present description are only used for matching the contents disclosed in the description, understood and read by those skilled in the art, and are not used for limiting the implementable restrictions of the present application, and thus do not have substantive technical significance. Any structural modification, change of the proportional relationship, or size adjustment should still fall within the scope encompassed in the technical contents disclosed in the present application without affecting the efficacy and the purpose that can be achieved by the present application.

FIG. 1 is a display effect diagram when a conventional display panel displays a monochromatic image;

FIG. 2 is a schematic view of an arrangement of first light-emitting elements in a display panel according to embodiments of the present application;

FIG. 3 is a schematic view of an arrangement of first light-emitting elements in another display panel according to embodiments of the present application;

FIG. 4 is a schematic view of an arrangement of first light-emitting elements in yet another display panel according to embodiments of the present application;

FIG. 5 is a schematic view of an arrangement of first light-emitting elements in yet another display panel according to embodiments of the present application;

FIG. 6 is a display effect diagram when a display panel displays a monochromatic image according to embodiments of the present application;

FIG. 7 is a schematic view of an arrangement of first light-emitting elements in yet another display panel according to embodiments of the present application;

FIG. 8 is a schematic view of an arrangement of first light-emitting elements in yet another display panel according to embodiments of the present application;

FIG. 9 is a schematic view of an arrangement of first light-emitting elements in yet another display panel according to embodiments of the present application;

FIG. 10 is a schematic view of an arrangement of first light-emitting elements in yet another display panel according to embodiments of the present application;

FIG. 11 is a schematic view of an arrangement of first light-emitting elements in yet another display panel according to embodiments of the present application;

FIG. 12 is a schematic view of an arrangement of first light-emitting elements in yet another display panel according to embodiments of the present application;

FIG. 13 is a schematic view of an arrangement of first light-emitting elements in yet another display panel according to embodiments of the present application;

FIG. 14 is a schematic view of an arrangement of first light-emitting elements in yet another display panel according to embodiments of the present application;

FIG. 15 is a schematic view of an arrangement of first light-emitting elements in yet another display panel according to embodiments of the present application;

FIG. 16 is a schematic view of an arrangement of first light-emitting elements in yet another display panel according to embodiments of the present application;

FIG. 17 is a schematic view of an arrangement of first light-emitting elements in yet another display panel according to embodiments of the present application;

FIG. 18 is a schematic view of an arrangement of first light-emitting elements in yet another display panel according to embodiments of the present application;

FIG. 19 is a schematic view of an arrangement of first light-emitting elements in yet another display panel according to embodiments of the present application;

FIG. 20 is a cross-sectional view of a display panel according to embodiments of the present application;

FIG. 21 is a schematic structural view of an electronic device according to embodiments of the present application;

FIG. 22 is a schematic flowchart of a method for manufacturing the display panel according to embodiments of the present application;

FIG. 23 is a schematic flowchart of a method for testing a first device wafer according to embodiments of the present application;

FIG. 24 is a distribution view of a dominant wavelength of a first device wafer according to embodiments of the present application;

FIG. 25 is a distribution view of a dominant wavelength of another first device wafer according to embodiments of the present application;

FIG. 26 is a distribution view of a dominant wavelength of yet another first device wafer according to embodiments of the present application;

FIG. 27 is a distribution view of a dominant wavelength of yet another first device wafer according to embodiments of the present application;

FIG. 28 is a schematic flowchart of a method for determining a wafer complementary group according to embodiments of the present application;

FIG. 29 is a schematic view of a calculation principle for determining a wafer complementary group according to embodiments of the present application;

FIG. 30 is a schematic view of a calculation principle for determining a carrier base plate according to embodiments of the present application;

FIG. 31 is a schematic view of an arrangement of first light-emitting elements in yet another display panel according to embodiments of the present application;

FIG. 32 is a schematic view of an arrangement of first light-emitting elements in yet another display panel according to embodiments of the present application;

FIG. 33 to FIG. 38 are schematic views of a principle for transferring a first light-emitting element according to embodiments of the present application; and

FIG. 39 is a schematic view of a calculation principle of a dominant wavelength of a light-emitting element according to embodiments of the present application.

### DETAILED DESCRIPTION

Embodiments in the present application will be described clearly and completely below with reference to the drawings in the embodiments of the present application. It may be understood by those skilled in the art that, with the development of technology and the emergence of new scenarios, the technical solutions according to the embodiments of the present application are applicable to similar technical problems.

For the active display panel in which the transfer process is needed to form a light-emitting element array, miniature LEDs are used in the display panel as light-emitting elements. The miniature LEDs may be the MINI LEDs or the Micro LEDs. Using the miniature LEDs in the display panel as the light-emitting elements has technical advantages such as high brightness, high contrast ratio, wide color gamut, fast response and long service life and is one of the most important display technologies after LCD and OLED.

The miniature LEDs need to be manufactured in batches using wafers. A great number of miniature LEDs of the same light-emitting color may be formed based on the same wafer by the semiconductor process, and then may be transferred to the array base plate of the display panel by the transfer process to form the light-emitting element array. When the miniature LEDs are manufactured on the wafer, the film layer structures of the miniature LEDs are generally required to be formed by the deposition process. Since there is the difference in composition and thickness of film layers of the miniature LEDs in different regions of the wafer in the manufacturing process, there is the difference in dominant wavelengths of the miniature LEDs in different regions of the wafer.

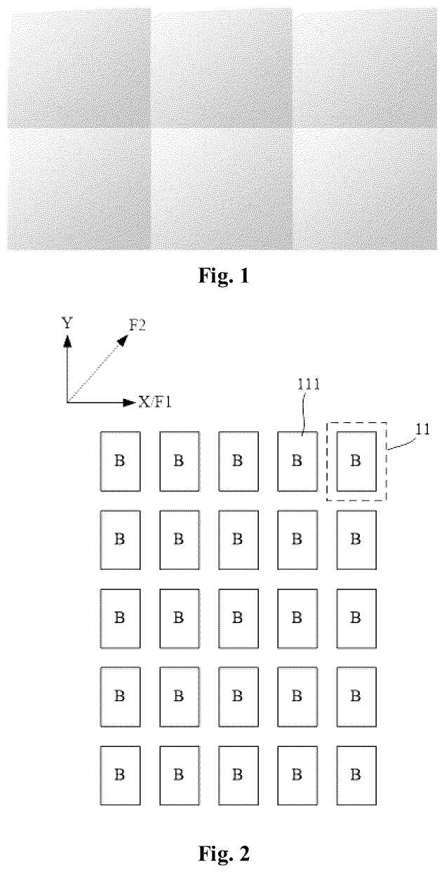

Referring to FIG. 1, FIG. 1 is a display effect diagram when a conventional display panel displays a monochromatic image. It may be seen from the above description that, since there is the difference in the dominant wavelengths of the miniature LEDs in different regions of the wafer, and under a condition that the miniature LEDs are used as the light-emitting elements of the display panel, the light-emitting elements of the same light-emitting color in the display panel have a plurality of different dominant wavelengths, so that there is the display difference in the light-emitting elements in different regions of the display panel, causing the non-uniform display of the display panel; when the display panel displays the monochromatic image, there are boundary stripes and non-uniform brightness in different regions, affecting the image display quality of the display panel.

In order to solve the above problems, embodiments of the present application provide a display panel which includes the display layer.

The display layer includes a plurality of first light-emitting units which are arranged in an array; one of the plurality of first light-emitting units includes at least one first light-emitting element which emits light of the first color.

The dominant wavelengths of the plurality of first light-emitting units satisfy: |D₁−D₂|>0.

D₁ represents the first difference between the dominant wavelengths of the first light-emitting elements in two of the plurality of first light-emitting units which are adjacent to each other along the first direction, and the first direction includes at least one of the row direction or the column direction of the array where the plurality of first light-emitting units are located.

D₂ represents the second difference between the dominant wavelengths of the first light-emitting elements in two of the plurality of first light-emitting units which are adjacent to each other along the second direction, the angle between the second direction and the first direction is greater than 0° and less than 90°.

It may be seen from the above description that, in the display panel according to the technical solution of the present application, since |D₁−D₂|>0, that is, D₁≠D₂, the two first light-emitting units which are adjacent to each other along the first direction and the two first light-emitting units which are adjacent to each other along the second direction may correspond to different dominant wavelength differences. The dominant wavelength which corresponds to the first direction is provided to be different from the dominant wavelength which corresponds to the second direction, so that complementarity in the display effect of the first light-emitting elements which have different dominant wavelengths in the display panel is achieved. Based on the adapted D₁ and the adapted D₂, the problem of non-uniform display of the display panel which is caused by the display difference in the light-emitting elements of the same color may be effectively solved.

In order to make the above objects, features and advantages of the present application more obvious and easily understood, the present application will be described in further detail below with reference to the drawings and the specific embodiments.

Referring to FIG. 2, FIG. 2 is a schematic view of an arrangement of first light-emitting elements in the display panel according to embodiments of the present application, and the display panel includes the display layer.

The display layer includes a plurality of first light-emitting units 11 which are arranged in an array; one of the plurality of first light-emitting units 11 includes at least one first light-emitting element 111 which emits light of the first color, and the dominant wavelengths of the plurality of first light-emitting units 11 satisfy: |D₁−D₂|>0.

D₁ represents the first difference between the dominant wavelengths of the first light-emitting elements 111 in two of the plurality of first light-emitting units 11 which are adjacent to each other along the first direction F1, and the first direction F1 includes at least one of the row direction X or the column direction Y of the array where the plurality of first light-emitting units 11 are located.

D₂ represents the second difference between the dominant wavelengths of the first light-emitting elements 111 in two of the plurality of first light-emitting units 11 which are adjacent to each other along the second direction F2, the angle between the second direction F2 and the first direction F1 is greater than 0° and less than 90°.

In the embodiments of the present application, the display layer includes at least one of the plurality of first light-emitting units 11; along the first direction F1, the difference between the dominant wavelength of the at least one of the plurality of first light-emitting units 11 and the dominant wavelengths of other ones of the plurality of first light-emitting units 11 is the first difference; and along the second direction F2, the difference between the dominant wavelength of the at least one of the plurality of first light-emitting units 11 and the dominant wavelengths of other ones of the plurality of first light-emitting units 11 is the second difference. In this way, the display complementarity may be achieved by the plurality of first light-emitting units 11 which have the difference between different dominant wavelengths to increase the display uniformity.

In FIG. 2, the example in which the first direction F1 includes the row direction X is given for illustration. In other embodiments, the first direction F1 may include the column direction Y or may include the row direction X and the column direction Y at the same time.

Optionally, the second direction F2 intersects with the row direction X and the column direction Y Optionally, the second direction F2 includes the connection direction between the first light-emitting unit 11 in the i-th row and the j-th column and the first light-emitting unit 11 in the (i+1)-th row and (j+1)-th column, and/or the connection direction between the first light-emitting unit 11 in the (i+1)-th row and j-th column and the first light-emitting unit 11 in the i-th row and (j+1)-th column. i and j are both positive integers, i is not greater than the total row number of the first light-emitting units 11, and j is not greater than the total column number of the first light-emitting units 11.

It should be noted that, in the embodiments of the present application, the difference between the dominant wavelengths of two first light-emitting elements 111 is the difference which is obtained by subtracting the smaller one of the dominant wavelengths of two first light-emitting elements 111 from the greater one of the dominant wavelengths of two first light-emitting elements 111; that is, D₁ and D₂ are both positive numbers, and based on this, D₃ and D₄ hereinafter are both positive numbers. Since the first light-emitting elements 111 emit light of the first color, the first light-emitting unit 11 is the set of the first light-emitting elements of the single color.

The first light-emitting elements 111 are arranged in an array in the display layer. The same first light-emitting unit 11 has the first light-emitting elements 111 which are arranged in m rows and n columns, and m and n are both positive integers. If m=n=1, the first light-emitting unit 11 has one first light-emitting element 111; and if at least one of m or n is greater than 1, the first light-emitting unit 11 has a plurality of first light-emitting elements 111 which are arranged in an array. If m is greater than 1, m rows of the plurality of first light-emitting elements 111 in the same first light-emitting unit 11 are m consecutive rows of the plurality of first light-emitting elements in the first light-emitting element array; and if n is greater than 1, n columns of the plurality of first light-emitting elements 111 in the same first light-emitting unit 11 are n consecutive columns of the plurality of first light-emitting elements in the first light-emitting element array. In the embodiments shown in FIG. 2, the example in which one of the plurality of first light-emitting units 11 includes one first light-emitting element 111 is given for illustration.

The display panel includes at least three types of the plurality of light-emitting elements of different light-emitting colors which are the red light-emitting elements R, the green light-emitting elements G and the blue light-emitting elements B for emitting red light, green light and blue light, respectively. In FIG. 2, the example in which that the plurality of first light-emitting elements 111 are the blue light-emitting elements B is given for illustration; and the plurality of first light-emitting elements 111 may be the red light-emitting elements R or the green light-emitting elements G which emit green light.

In the embodiments of the present application, the two first light-emitting units 11 which are adjacent to each other along the first direction F1 refer to two first light-emitting units 11 which are consecutively arranged along the first direction F1; that is, there is no other first light-emitting units 11 between the two first light-emitting units 11 which are adjacent to each other along the first direction F1. There may be a light-emitting unit which includes a light-emitting element of other colors (non-first color) between the two first light-emitting units 11 which are adjacent to each other along the first direction F1; if the plurality of first light-emitting elements 111 are the blue light-emitting elements B, there may be a light-emitting unit which includes a red light-emitting element R and/or a light-emitting unit which includes a green light-emitting element G between the two first light-emitting units 11 which are adjacent to each other along the first direction F1.

Similarly, in the embodiments of the present application, the two first light-emitting units 11 which are adjacent to each other along the second direction F2 refer to two first light-emitting units 11 which are consecutively arranged along the second direction F2; that is, there is no other first light-emitting units 11 between the two first light-emitting units 11 which are adjacent to each other along the second direction F2. There may be a light-emitting unit which includes a light-emitting element of other colors between the two first light-emitting units 11 which are adjacent to each other along the second direction F2.

In the embodiments of the present application, since |D₁−D₂1>0, that is, D₁≠D₂, the two first light-emitting units 11 which are adjacent to each other along the first direction F1 and the two first light-emitting units 11 which are adjacent to each other along the second direction F2 may correspond to different dominant wavelength differences. The dominant wavelength which corresponds to the first direction F1 is provided to be different from the dominant wavelength which corresponds to the second direction F2, so that the complementarity in the display effect of the plurality of first light-emitting elements 111 which have different dominant wavelengths in the display panel is achieved. Based on the adapted D₁ and the adapted D₂, the problem of non-uniform display of the display panel which is caused by the display difference in the light-emitting elements of the same color may be effectively solved.

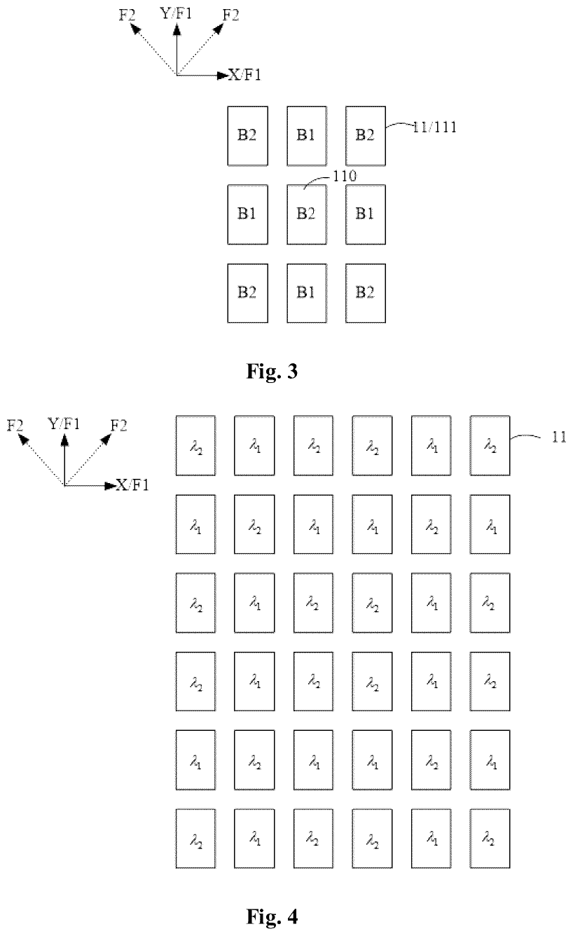

Referring to FIG. 3, FIG. 3 is a schematic view of an arrangement of first light-emitting elements in another display panel according to embodiments of the present application. In FIG. 3, the example in which the first direction F1 includes the row direction X and the column direction Y is given for illustration. In other embodiments, the first direction F1 may include one of the row direction X and the column direction Y In FIG. 3, the second direction F2 includes two diagonal directions of nine first light-emitting units 11 which are arranged in the 3×3 array. In other embodiments, the second direction F2 may include at least one of two diagonal directions of the nine first light-emitting units 11 which are arranged in the 3×3 array.

In an embodiment, as shown in FIG. 3, in the nine first light-emitting units 11 which are arranged in the 3×3 array, the first light-emitting unit 11 which is located in the middle is set as the first main light-emitting unit 110. Along the first direction F1, the difference between the dominant wavelength of the first light-emitting element 111 in the first main light-emitting unit 110 and the dominant wavelengths of the first light-emitting elements 111 in the first light-emitting units 11 which are adjacent to the first light-emitting element 111 in the first main light-emitting unit 110 is D₁. Along the second direction F2, the difference between the dominant wavelength of the first light-emitting element 111 in the first main light-emitting unit 110 and the dominant wavelengths of the first light-emitting elements 111 in the first light-emitting units 11 which are adjacent to the first light-emitting element 111 in the first main light-emitting unit 110 is D₂.

The first main light-emitting unit 110 is the first light-emitting unit 11 which is located in the non-peripheral edge position of the first light-emitting unit array. Therefore, under a condition that the first direction F1 includes the row direction X and the column direction Y, the first main light-emitting unit 110 has four first light-emitting units 11 which are adjacent to the first main light-emitting unit 110 along the first direction F1; and under a condition that the second direction F2 includes two diagonal directions, the first main light-emitting unit 110 has four first light-emitting units 11 which are adjacent to the first main light-emitting unit 110 along the second direction F2.

In FIG. 3, the example in which each of the first light-emitting units 11 includes one first light-emitting element 111 is given for illustration. The difference between the dominant wavelength of the first light-emitting element 111 which is located in the middle and the dominant wavelengths of the four first light-emitting elements 111 which are adjacent to the first light-emitting element 111 which is located in the middle along the row direction X and the column direction Y is D₁, and the difference between the dominant wavelength of the first light-emitting element 111 which is located in the middle and the dominant wavelengths of the four first light-emitting elements 111 which are adjacent to the first light-emitting element 111 which is located in the middle along the diagonal direction of the array is D₂.

As shown in FIG. 3, taking for the example that the first light-emitting elements 111 are the blue light-emitting elements B, the dominant wavelength of the blue light which is emitted by the first light-emitting element 111 in the first main light-emitting unit 110 is λB₂ or approximately λ_{B2}. Along the first direction F1, the dominant wavelengths of the first light-emitting elements 111 in the first light-emitting units 11 which are adjacent to the first main light-emitting unit 110 are equal or approximately equal, and the dominant wavelengths of the first light-emitting units 11 which are adjacent to the first main light-emitting unit 110 along the first direction F1 may be λ_{B1} or approximately λ_{B1}. Along the second direction F2, the dominant wavelengths of the first light-emitting elements 111 in the first light-emitting units 11 which are adjacent to the first main light-emitting unit 110 are equal or approximately equal, and the dominant wavelengths of the first light-emitting units 11 which are adjacent to the first main light-emitting unit 110 along the second direction F2 may be λ_{B2} or approximately λ_{B2}. In this embodiment, the display layer includes two types of blue light-emitting elements B (B1 and B2) which have different dominant wavelengths, and the dominant wavelengths of B1 and B2 are λ_{B1} and λ_{B2}, respectively, λ_{B1}≠λ_{B2}.

Optionally, it may be set that D₁>D₂. In this way, in the two first light-emitting units 11 which are adjacent to each other along the first direction F1, the difference between the dominant wavelengths of the first light-emitting elements 111 is relatively small, and the first light-emitting elements 111 in the two first light-emitting units 11 have equal or approximately equal dominant wavelengths; and the difference between the dominant wavelengths of two first light-emitting units 11 which are adjacent to each other along the second direction F2 is relatively small, so that complementarity in the difference between the dominant wavelengths which correspond to the first light-emitting units 11 which are adjacent to each other along the first direction F1 and the difference between the dominant wavelengths which correspond to the first light-emitting units 11 which are adjacent to each other along the second direction F2 is achieved, and the complementarity in the display effect of the plurality of first light-emitting elements 111 which have different dominant wavelengths in the display panel is achieved to increase the display uniformity of the entire display panel.

Taking for the example that the first light-emitting elements 111 are the blue light-emitting elements B, as shown in FIG. 3, since D₁>D₂, though there is the difference |λ_{B1}−λ_{B2}| between the dominant wavelength of the first light-emitting element 111 in the first main light-emitting unit 110 and the dominant wavelengths of the four first light-emitting elements 111 which are adjacent to the first light-emitting element 111 in the first main light-emitting unit 110 along the first direction F1, the difference |λ_{B1}−λ_{B2}| along the first direction F1 may be compensated by the first light-emitting elements 111 which have the dominant wavelength λ_{B2} and are adjacent to the first light-emitting element 111 in the first main light-emitting unit 110 along the second direction F2 to achieve the complementarity in the display effect of the plurality of first light-emitting elements 111 which have different dominant wavelengths in the display panel.

In an embodiment of the present application, one of the plurality of first light-emitting units 11 includes one first light-emitting element 111; or one of the plurality of first light-emitting units 11 includes p first light-emitting elements, p is a positive integer greater than 1, the difference between the dominant wavelengths of two first light-emitting elements 111 in the same first light-emitting unit 11 is not greater than the first threshold which is less than or equal to D₂.

Optionally, if the plurality of first light-emitting elements 111 are included in the same first light-emitting unit 11, the difference between the dominant wavelength of one of the plurality of first light-emitting elements 111 and the dominant wavelengths of other ones of the plurality of first light-emitting elements 111 may be set to be the first threshold.

If one of the plurality of first light-emitting units 11 includes one first light-emitting element 111, in the first light-emitting element array, the difference between the dominant wavelengths of two first light-emitting elements 111 which are adjacent to each other along the first direction F1 is D₁, and the difference between the dominant wavelengths of two first light-emitting elements 111 which are adjacent to each other along the second direction F2 is D₂. With the unequal differences in the dominant wavelengths, the complementarity in the display effect is achieved between the two first light-emitting elements 111 which are adjacent to each other along the first direction F1 and the two first light-emitting elements 111 which are adjacent to each other along the second direction F2 to reduce the problem of non-uniform display of the display panel which is caused by the display difference in the plurality of first light-emitting elements 111.

If one of the plurality of first light-emitting units 11 includes p first light-emitting elements 111, the first light-emitting element array is divided into a plurality of sub-arrays. One of the plurality of sub-arrays is used as one first light-emitting unit 11 which includes p first light-emitting elements 111. The p first light-emitting elements 111 in the same first light-emitting unit 11 are arranged in m rows and n columns, and p=m*n. Since the first threshold is less than or equal to D₂, the p first light-emitting elements 111 in the same first light-emitting unit 11 have equal or approximate dominant wavelengths, which may facilitate the scheme design in which complementarity in the dominant wavelengths of the p first light-emitting elements 111 in the same first light-emitting unit 11 as a whole and the dominant wavelengths of p first light-emitting elements 111 in one of other first light-emitting units 11 may be achieved.

Referring to FIG. 4, FIG. 4 is a schematic view of an arrangement of first light-emitting elements in yet another display panel according to embodiments of the present application. Based on the above embodiments, in the embodiment shown in FIG. 4, in the array where the plurality of first light-emitting units 11 are located, and along the row direction X, the plurality of first light-emitting units 11 which have the first dominant wavelength and the plurality of first light-emitting units 11 which have the second dominant wavelength are alternately arranged; along the column direction Y, the plurality of first light-emitting units 11 which have the first dominant wavelength and the plurality of first light-emitting units 11 which have the second dominant wavelength are alternately arranged; the difference between the first dominant wavelength and the second dominant wavelength is not less than the second threshold which is greater than or equal to D₁. The first dominant wavelength is set to be λ₁, the second dominant wavelength is set to be λ₂, and |λ₁−λ₂|≥D₁.

If one of the plurality of first light-emitting units 11 has one light-emitting element 111, one of the plurality of first light-emitting units 11 which have the first dominant wavelength has one light-emitting element 111 which has the dominant wavelength λ₁, and one of the plurality of first light-emitting units 11 which have the second dominant wavelength has one light-emitting element 111 which has the dominant wavelength λ₂. If one of the plurality of first light-emitting units 11 has p first light-emitting elements 111, the dominant wavelength of the first light-emitting elements 111 in one of the plurality of first light-emitting units 11 which have the first dominant wavelength is λ₁ or approximately λ₁, and the dominant wavelength of the first light-emitting elements 111 in one of the plurality of first light-emitting units 11 which have the second dominant wavelength is λ₂ or approximately λ₂.

In an embodiment, in the array where the plurality of first light-emitting units 11 are located, as shown in FIG. 4, for rows of plurality of first light-emitting units 11, the plurality of first light-emitting units 11 which have the first dominant wavelength and the plurality of first light-emitting units 11 which have the second dominant wavelength may be alternately arranged; for columns of plurality of first light-emitting units 11, the plurality of first light-emitting units 11 which have the first dominant wavelength and the plurality of first light-emitting units 11 which have the second dominant wavelength may be alternately arranged; and in rows and columns, the plurality of first light-emitting units 11 which have the first dominant wavelength and the plurality of first light-emitting units 11 which have the second dominant wavelength may be alternately arranged. Arranging the plurality of first light-emitting units 11 which have two dominant wavelengths in a regular and cyclic pattern achieves the complementarity in the display effect of the plurality of first light-emitting elements 111 which have two dominant wavelengths in the display panel to reduce the problem of non-uniform display of the display panel which is caused by the display difference in the plurality of first light-emitting elements 111.

In other embodiments, in at least one row of the plurality of first light-emitting units 11, the plurality of first light-emitting units 11 which have the first dominant wavelength and the plurality of first light-emitting units 11 which have the second dominant wavelength may be alternately arranged, and/or in at least one column of the plurality of first light-emitting units 11, the plurality of first light-emitting units 11 which have the first dominant wavelength and the plurality of first light-emitting units 11 which have the second dominant wavelength may be alternately arranged. Alternately arranging the plurality of first light-emitting units 11 which have two dominant wavelengths along the first direction F1 achieves the display complementarity in different dominant wavelengths and increases the display uniformity.

In the embodiments of the present application, if one of the plurality of first light-emitting units 11 includes one first light-emitting element 111, the dominant wavelengths of the plurality of first light-emitting units 11 are the dominant wavelength of the first light-emitting element 111; if one of the plurality of first light-emitting units 11 includes a plurality of first light-emitting elements 111 and the dominant wavelengths of the plurality of first light-emitting elements 111 are equal or approximately equal, the dominant wavelengths of the plurality of first light-emitting units 11 are the average value of the dominant wavelengths of the plurality of first light-emitting elements 111, or the equivalent dominant wavelength when the plurality of first light-emitting elements 111 emit light at the same time.

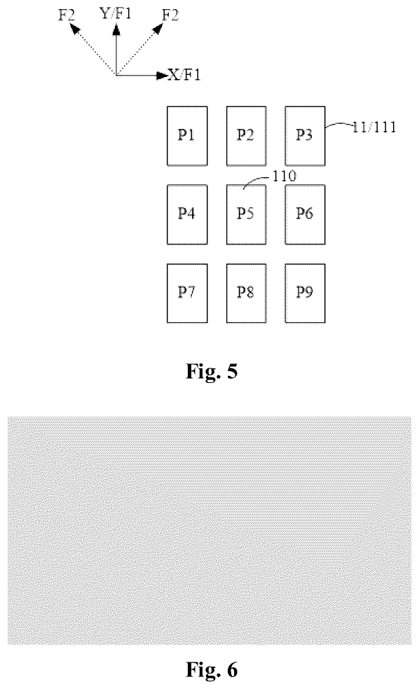

Referring to FIG. 5, FIG. 5 is a schematic view of an arrangement of first light-emitting elements in yet another display panel according to embodiments of the present application. Based on the above embodiments, in the embodiment shown in FIG. 5, the first light-emitting unit 11 includes the first main light-emitting unit 110, the sum of the absolute values of the difference between the dominant wavelength of the first main light-emitting unit 110 and the dominant wavelengths of four first light-emitting units 11 which are adjacent to the first main light-emitting unit 110 along the first direction F1 is the first sum value, and the sum of the absolute values of the difference between the dominant wavelength of the first main light-emitting unit 110 and the dominant wavelengths of four first light-emitting units 11 which are adjacent to the first main light-emitting unit 110 along the second direction F2 is the second sum value, and the first sum value is greater than or less than twice of the second sum value. For the array where the plurality of first light-emitting units 11 are located, in nine first light-emitting units 11 which intersect in three consecutive rows and three consecutive columns, the first light-emitting unit 11 which is located in the middle is the first main light-emitting unit 110.

As shown in FIG. 5, the nine first light-emitting units 11 are set to be P1 to P9 in sequence, the dominant wavelengths are set to be λ_{P1} to λ_{P9} in sequence, and P5 is the first main light-emitting unit 110. The first sum value is S₁, the second sum value is S₂, and S₁ and S₂ satisfies the following relationship:

$${S}_{1} = \vert {λ}_{P 5} - {λ}_{P 2} \vert + \vert {λ}_{P 5} - {λ}_{P 4} \vert + \vert {λ}_{P 5} - {λ}_{P 6} \vert + \vert {λ}_{P 5} - {λ}_{P 8} \vert \\ {S}_{2} = \vert {λ}_{P 5} - {λ}_{P 1} \vert + \vert {λ}_{P 5} - {λ}_{P 3} \vert + \vert {λ}_{P 5} - {λ}_{P 7} \vert + \vert {λ}_{P 5} - {λ}_{P 9} \vert \\ {S}_{1} \geq 2 {S}_{2}$$

In the embodiment shown in FIG. 5, since S₁≥2S² is satisfied, though the difference between the dominant wavelength of P5 and the dominant wavelengths of P2, P4, P6 and P8 which are adjacent to P5 along the first direction F1 is relatively great, the difference between the dominant wavelength of P5 and the dominant wavelengths of P1, P3, P7 and P9 which are adjacent to P5 along the second direction F2 is relatively small, the difference between the dominant wavelength of P5 and the dominant wavelengths of P2, P4, P6 and P8 may be compensated by P1, P3, P7, and P9, thereby achieving the complementarity in the display effect of the plurality of first light-emitting elements 111 which have different dominant wavelengths in the display panel to reduce the problem of non-uniform display of the display panel which is caused by the display difference in the plurality of first light-emitting elements 111.

Optionally, in the embodiment shown in FIG. 5, P2, P4, P6 and P8 may be set to have the equal or approximately equal dominant wavelengths; if the dominant wavelengths of the first light-emitting units 11 may be equal to or approximately equal to the first dominant wavelength, and P1, P3, P5, P7 and P9 may be set to have the equal or approximately equal dominant wavelengths: if the dominant wavelengths of the first light-emitting units 11 may be equal to or approximately equal to the second dominant wavelength, and the first dominant wavelength is not equal to the second dominant wavelength, the difference between the dominant wavelength of P5 and the dominant wavelengths of the first light-emitting units 11 which are adjacent to P5 along the first direction F1 is the first difference D₁, the difference between the dominant wavelength of P5 and the dominant wavelengths of the first light-emitting units 11 which are adjacent to P5 along the second direction F2 is the second difference D₂, and D₁>D₂ is satisfied.

Referring to FIG. 6, FIG. 6 is a display effect diagram when a display panel displays a monochromatic image according to embodiments of the present application, taking for the example that the first light-emitting elements 111 are blue light-emitting elements B, when the display panel displays a solid blue image, compared with the embodiment shown in FIG. 1, under a condition that the blue light-emitting elements B are arranged based on the technical solution of the embodiments of the present application, the uniformity of the display image may be effectively increased, and the problem of boundary stripes and non-uniform brightness in different regions may be eliminated.

For one first main light-emitting unit 110, under a condition that the difference between the dominant wavelength of the first main light-emitting unit 110 and the dominant wavelengths of the first light-emitting units 11 which are adjacent to the first main light-emitting unit 110 along the first direction F1 is relatively great (that is, the first difference D₁), the difference between the dominant wavelength of the first main light-emitting unit 110 and the dominant wavelengths of the first light-emitting units 11 which are adjacent to the first main light-emitting unit 110 along the second direction F2 may be set to be relatively small (that is, the second difference D₂). The dominant wavelength differences which correspond to the first main light-emitting unit 110 along the first direction F1 and the second direction F2 are provided to be different from each other, so that the display panel may achieve the complementarity in the display effect of the plurality of first light-emitting elements 111 which have different dominant wavelengths.

In the embodiments of the present application, one of the plurality of first light-emitting units 11 includes at least one first light-emitting element 111 which emits light of the first color and are the set of the first light-emitting elements 111; one of the plurality of first light-emitting units may include the first light-emitting elements 111 which are arranged in m rows and n columns, and m and n are both positive integers.

As described above, in the embodiments of the present application, the first difference D₁ may be provided to be different from the second difference D₂, so that the complementarity in the display effect of the first light-emitting elements 111 which have different dominant wavelengths may be achieved. If the value of m or n is greater than 2, one of the first light-emitting elements 11 has a relatively great number of first light-emitting elements 111. For one first main light-emitting element 110, the first main light-emitting element 110 and the first light-emitting units 11 which are adjacent to the first main light-emitting unit 110 along the first direction F1 may have a region with a relatively great area; and correspondingly, the first main light-emitting element 110 and the first light-emitting units 11 which are adjacent to the first main light-emitting unit 110 along the second direction F2 may have a region with a relatively great area. Under a condition that the display non-uniformity which is caused by the difference between the dominant wavelength of the first main light-emitting element 110 and the dominant wavelengths of the first light-emitting units 11 which are adjacent to the first main light-emitting unit 110 along the first direction F1 is compensated by the first light-emitting units 11 which are adjacent to the first main light-emitting unit 110 along the first direction F1, since the compensation effect is greatly reduced by the relatively great areas, there are display stripes when the user views the display image from a short distance.

In order to solve the above problem, m and n both may be set to be positive integers which are not greater than 2, so that one of the plurality of first light-emitting units 11 may have a moderate number of first light-emitting elements 111 to prevent the first main light-emitting unit 110 and the first light-emitting units 11 which are adjacent to the first main light-emitting unit 110 along the first direction F1 from occupying a region with a relatively great area and prevent the first main light-emitting unit 110 and the first light-emitting units 11 which are adjacent to the first main light-emitting unit 110 along the second direction F2 from occupying a region with a relatively great area. Therefore, the display panel may achieve display compensation between the first light-emitting elements 111 which have different dominant wavelengths in a region with a relatively small area, and there is the desired image display effect when the user views the display image from the short distance.

In a display panel for displaying an image to the user from a long distance, such as an outdoor advertisement display screen and an indoor advertisement display screen, since the display panel is mainly used for displaying the image to the user from a relatively long distance, m and/or n may be set to be greater than 2; under this condition, the distance from the user to the display panel is relatively great, the image distance from the plurality of first light-emitting units 11 to the human eye is relatively great, and the image area which is formed by the first main light-emitting unit 110 and the first light-emitting units 11 which are adjacent the first main light-emitting unit 110 along the first direction F1 in the human eye is relatively small. When the image is viewed from the long distance, the dominant wavelength differences which correspond to the first main light-emitting unit 110 along the first direction F1 and the second direction F2 are provided to be different from each other, so that the display panel may achieve the complementarity in the display effect of the plurality of first light-emitting elements 111 which have different dominant wavelengths.

In the embodiments of the present application, the display layer may have c types of the plurality of first light-emitting units 11 which have dominant wavelengths different from each other, and c is a positive integer greater than 1; the display layer is evenly divided into a plurality of sub-display regions which are arranged in an array; in the same sub-display region, the number of the plurality of first light-emitting units is not less than c, and the dominant wavelengths of at least c first light-emitting units 11 are different from each other.

Based on the above embodiments, the display complementarity between the first light-emitting elements 111 which have different dominant wavelengths can be achieved; further, the display layer is evenly divided into the plurality of sub-display regions, and one of the plurality of sub-display regions includes at least c first light-emitting units 11, so that one of the plurality of sub-display regions may include c types of first light-emitting units 11 which have dominant wavelengths different from each other. In this way, in the same sub-display region, the display complementarity may be achieved between c types of first light-emitting units 11 which have dominant wavelengths different from each other in the sub-display region, and the complementarity in the dominant wavelengths of the first light-emitting units 11 which have different dominant wavelengths in the same sub-display region may be achieved, increasing the display uniformity of the sub-display regions. In addition, since one of the plurality of sub-display regions includes c types of first light-emitting units 11 which have dominant wavelengths different from each other, the plurality of sub-display regions have the same display effect, avoiding the non-uniform display which is caused by the difference in dominant wavelength types in different sub-display regions.

The display layer is evenly divided into the plurality of sub-display regions, and the plurality of first light-emitting units 11 are arranged based on the plurality of sub-display regions, so that the plurality of first light-emitting units 11 which have different dominant wavelengths may be cyclically and regularly arranged in the display layer based on the plurality of sub-display regions, facilitating the arrangement of the first light-emitting elements 111 in the display layer.

Optionally, one of the plurality of sub-display regions may include the first light-emitting units 11 in three rows and three columns, so that the first light-emitting elements 111 which have different dominant wavelengths may be cyclically and regularly arranged in the display layer based on the plurality of sub-display regions, the first light-emitting elements 111 in the plurality of sub-display regions are arranged based on the nine-square grid shown in FIG. 5, and positions of the first light-emitting elements 111 in the plurality of sub-display regions may be provided based on the dominant wavelengths of the light-emitting elements, facilitating the implementation of the scheme design.

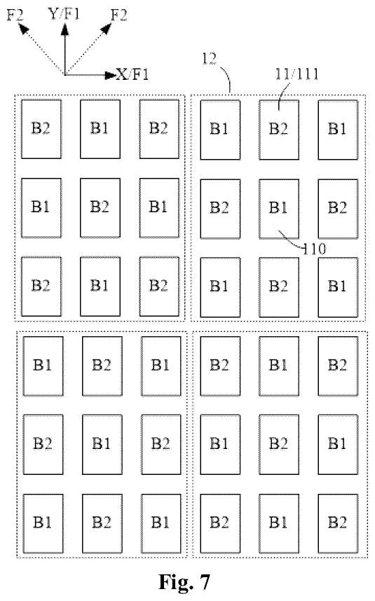

Referring to FIG. 7, FIG. 7 is a schematic view of an arrangement of first light-emitting elements in yet another display panel according to embodiments of the present application. Based on the above embodiments, in the embodiment shown in FIG. 7, c=2, one of the plurality of first light-emitting units 11 has one first light-emitting element 111 (that is, m=n=1), and one of the plurality of sub-display regions 12 has the plurality of first light-emitting units 11 in three rows and three columns. Taking for the example that the first light-emitting elements 111 are the blue light-emitting elements B, two types of blue light-emitting elements B which have different dominant wavelengths are B1 and B2, respectively.

In the embodiment shown in FIG. 7, if the first light-emitting element 111 in the first main light-emitting unit 110 in the sub-display region 12 is B1, the first light-emitting elements 111 in the plurality of first light-emitting units 11 which are adjacent to the first main light-emitting units 110 along the first direction F1 are B2, and the first light-emitting elements 111 in the plurality of first light-emitting units 11 which are adjacent to the first main light-emitting units 110 along the second direction F2 are B1, and D₁>D₂ is satisfied. If the first light-emitting element 111 in the first main light-emitting unit 110 in the sub-display region 12 is B2, the first light-emitting elements 111 in the plurality of first light-emitting units 11 which are adjacent to the first main light-emitting units 110 along the first direction F1 are B1, and the first light-emitting elements 111 in the plurality of first light-emitting units 11 which are adjacent to the first main light-emitting units 110 along the second direction F2 are B2, and D₁>D₂ is satisfied.

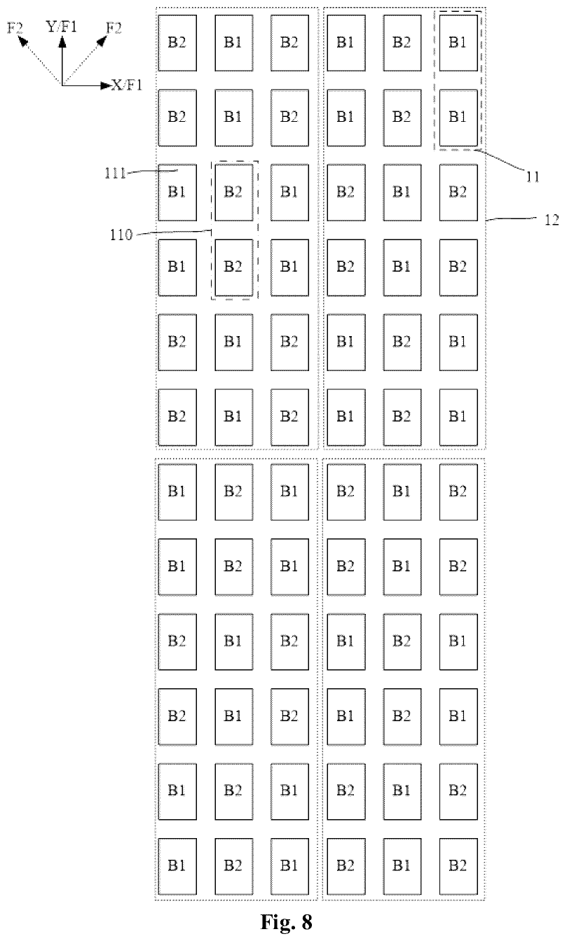

Referring to FIG. 8, FIG. 8 is a schematic view of an arrangement of first light-emitting elements in yet another display panel according to embodiments of the present application. Based on the above embodiments, in the embodiment shown in FIG. 8, c=2, one of the plurality of first light-emitting units 11 has two first light-emitting elements 111 which are consecutively arranged along the column direction Y (that is, m=2, n=1), and one of the plurality of sub-display regions 12 has the plurality of first light-emitting units 11 in three rows and three columns. Similarly, in FIG. 8, taking for the example that the first light-emitting elements 111 are blue light-emitting elements B, two types of blue light-emitting elements B which have different dominant wavelengths are B1 and B2, respectively.

In the embodiment shown in FIG. 8, for the sub-display region 12 in which two B1 are the first main light-emitting unit 110 and the sub-display region 12 in which two B2 are the first main light-emitting unit 110, D₁>D₂ may be satisfied.

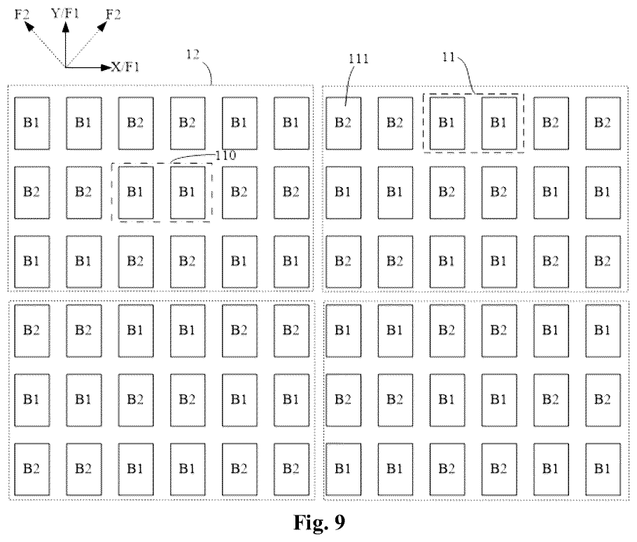

Referring to FIG. 9, FIG. 9 is a schematic view of an arrangement of first light-emitting elements in yet another display panel according to embodiments of the present application. Based on the above embodiments, in the embodiment shown in FIG. 9, c=2, one of the plurality of first light-emitting units 11 has two first light-emitting elements 111 which are consecutively arranged along the row direction X (that is, m=1, n=2), and one of the plurality of sub-display regions 12 has the plurality of first light-emitting units 11 in three rows and three columns. Similarly, in FIG. 9, taking for the example that the first light-emitting elements 111 are blue light-emitting elements B, two types of blue light-emitting elements B which have different dominant wavelengths are B1 and B2, respectively.

In the embodiment shown in FIG. 9, for the sub-display region 12 in which two B1 are the first main light-emitting unit 110 and the sub-display region 12 in which two B2 are the first main light-emitting unit 110, D₁>D₂ may be satisfied.

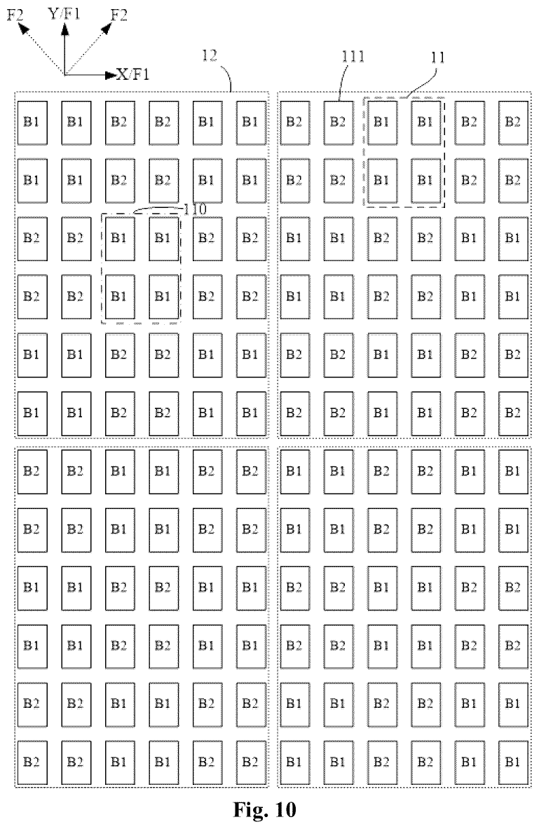

Referring to FIG. 10, FIG. 10 is a schematic view of an arrangement of first light-emitting elements in yet another display panel according to embodiments of the present application. Based on the above embodiments, in the embodiment shown in FIG. 10, c=2, one of the plurality of first light-emitting units 11 has four first light-emitting elements 111 which are consecutively arranged along two rows and two columns (that is, m=n=2), and one of the plurality of sub-display regions 12 has the plurality of first light-emitting units 11 in three rows and three columns. Similarly, in FIG. 10, taking for the example that the first light-emitting elements 111 are blue light-emitting elements B, two types of blue light-emitting elements B which have different dominant wavelengths are B1 and B2, respectively.

In the embodiment shown in FIG. 10, for the sub-display region 12 in which four B1 are the first main light-emitting unit 110 and the sub-display region 12 in which four B2 are the first main light-emitting unit 110, D₁>D₂ may be satisfied.

In the embodiments shown in FIG. 7 to FIG. 10, the example in which the first direction F1 includes the row direction X and the column direction Y and the second direction F2 includes two diagonal directions is given for illustration. In these embodiments, the display panel includes two types of the plurality of first light-emitting units 11 which have different dominant wavelengths, that is, c=2. Taking for the example that the first light-emitting elements 11 are blue light-emitting elements B, one type of the plurality of first light-emitting units 11 include two first blue light-emitting elements B1, and the other type of the plurality of first light-emitting units 11 include two second blue light-emitting elements B2; the dominant wavelength of the first blue light elements B1 is different from the dominant wavelength of the second blue light elements B2, and the difference between the dominant wavelength of the first blue light elements B1 and the dominant wavelength of the second blue light elements B2 is not less than the second threshold.

For the convenience of illustration, in the embodiments shown in FIG. 7 to FIG. 10, only four sub-display regions 12 are shown; in the actual display panel, the number of the plurality of sub-display regions 12 may be provided based on the number of the first light-emitting elements 111 in the display panel, which is not limited by the embodiments of the present application.

In an implementation of an embodiment of the present application, along the first direction F1, the difference between the dominant wavelengths of adjacent two of the plurality of first light-emitting units 11 is the first difference, facilitating the arrangement of the plurality of first light-emitting units 11 along the first direction. In this embodiment, the difference between the dominant wavelengths of the plurality of first light-emitting units 11 which are adjacent to each other along the row direction X may be set to be the first difference; or the difference between the dominant wavelengths of the plurality of first light-emitting units 11 which are adjacent to each other along the column direction Y may be set to be the first difference; or as shown in any one of FIG. 7 to FIG. 10, the difference between the dominant wavelengths of the plurality of first light-emitting units 11 which are adjacent to each other along the row direction X may be set to be the first difference, and the difference between the dominant wavelengths of the plurality of first light-emitting units 11 which are adjacent to each other along the column direction Y may be set to be the first difference.

In the embodiments of the present application, as described above, one of the plurality of first light-emitting units 11 has the first light-emitting elements 111 which are arranged in m rows and n columns, and m and n are both positive integers. Under a condition that c=2, m=n=1, or at least one of m or n is greater than 1.

As shown in FIG. 7, under a condition that c=2, if m=n=1, one of the plurality of first light-emitting units 11 includes one first light-emitting element 111; in this embodiment, along the row direction X and the column direction Y, two types of first light-emitting elements 111 which have different dominant wavelengths are alternately arranged, so that two types of first light-emitting elements 111 which have different dominant wavelengths achieve the display complementarity to increase the display uniformity.

As shown in FIG. 8, under a condition that c=2, if m=2 and n=1, one of the plurality of first light-emitting units 11 includes two first light-emitting elements 111 which are consecutively arranged along the column direction Y; in this embodiment, along the row direction X and the column direction Y, two types of first light-emitting elements 111 which have different dominant wavelengths are alternately arranged, so that two types of first light-emitting elements 111 which have different dominant wavelengths achieve the display complementarity to increase the display uniformity.

As shown in FIG. 9, under a condition that c=2, if m=1 and n=2, one of the plurality of first light-emitting units 11 includes two first light-emitting elements 111 which are consecutively arranged along the row direction X; in this embodiment, along the row direction X and the column direction Y, two types of first light-emitting elements 111 which have different dominant wavelengths are alternately arranged, so that two types of first light-emitting elements 111 which have different dominant wavelengths achieve the display complementarity to increase the display uniformity.

As shown in FIG. 10, under a condition that c=2, if m=n=2, one of the plurality of first light-emitting units 11 includes four first light-emitting elements 111 which are arranged in two rows and two columns; in this embodiment, along the row direction X and the column direction Y, two types of first light-emitting elements 111 which have different dominant wavelengths are alternately arranged, so that two types of first light-emitting elements 111 which have different dominant wavelengths achieve the display complementarity to increase the display uniformity.

Under a condition that c=2, the values of m and n are not limited by the embodiments shown in FIG. 7 to FIG. 11; when the display panel is used in a scene in which an image is displayed from a long distance, m and/or n may be greater than 2.

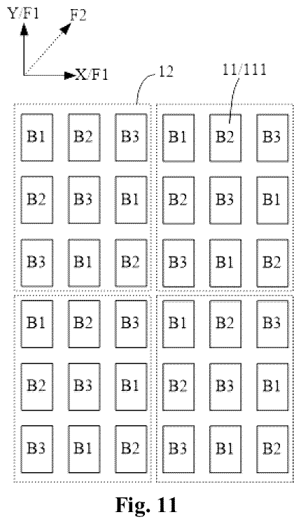

Referring to FIG. 11, FIG. 11 is a schematic view of an arrangement of first light-emitting elements in yet another display panel according to embodiments of the present application. Based on the above embodiments, in the embodiment shown in FIG. 11, c=3, one of the plurality of first light-emitting units 11 has one first light-emitting element 111 (that is, m=n=1), and one of the plurality of sub-display regions 12 has the plurality of first light-emitting units 11 in three rows and three columns. In this embodiment, the first direction F1 includes the row direction X and the column direction Y, the second direction F2 includes one diagonal direction, the first light-emitting elements 111 are blue light-emitting elements B, and the three types of blue light-emitting elements B which have different dominant wavelengths are B1, B2, and B3, respectively. The second direction F2 is the diagonal direction between the positive direction of the row direction X and the positive direction of the column direction Y which are shown in FIG. 11.

In the embodiment shown in FIG. 11, for any two first light-emitting units 11 which are adjacent to each other along the first direction F1, the first light-emitting element 111 in one of the first light-emitting units 11 is one of B1, B2, and B3, and the first light-emitting element 111 in the other of the first light-emitting units 11 is another one of B1, B2, and B3, that is, D₁ is the difference between the dominant wavelengths of two of B1, B2; since the dominant wavelengths of B1, B2 and B3 are not equal to each other, D₁ is greater than 0. A part of the plurality of first light-emitting units 11 and the first light-emitting units 11 which are adjacent to the part of the plurality of first light-emitting units 11 along the second direction F2 have the first light-emitting elements 111 of the same light-emitting color; as shown in FIG. 11, along the second direction F2, there are a plurality of pairs of B1 which are adjacent to each other, a plurality of pairs of B2 which are adjacent to each other, and a plurality of pairs of B3 which are adjacent to each other; for a pair of B1, a pair of B2, and a pair of B3 which are adjacent to each other, the corresponding D₂ is 0, so that D₁>D₂ is satisfied.

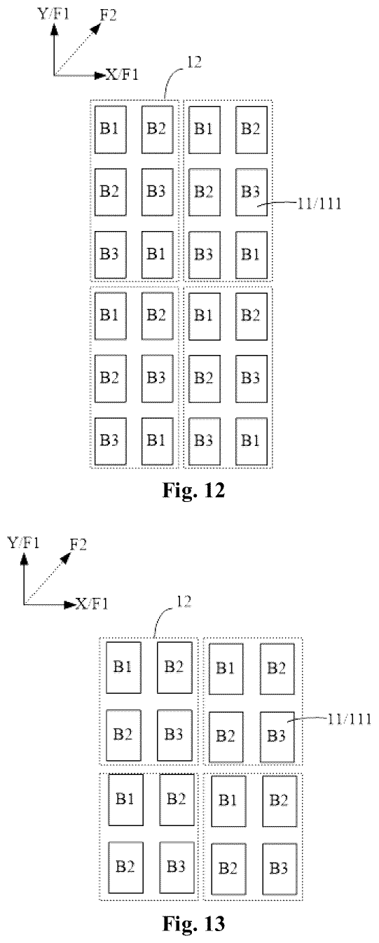

Referring to FIG. 12, FIG. 12 is a schematic view of an arrangement of first light-emitting elements in yet another display panel according to embodiments of the present application. Based on the above embodiments, in the embodiment shown in FIG. 12, c=3, one of the plurality of first light-emitting units 11 has one first light-emitting element 111 (that is, m=n=1), and one of the plurality of sub-display regions 12 has the plurality of first light-emitting units 11 in three rows and two columns. In this embodiment, the first direction F1 includes the row direction X and the column direction Y, the second direction F2 includes one diagonal direction, the first light-emitting elements 111 are blue light-emitting elements B, and the three types of blue light-emitting elements B which have different dominant wavelengths are B1, B2, and B3, respectively. The second direction F2 is the diagonal direction between the positive direction of the row direction X and the positive direction of the column direction Y which are shown in FIG. 12.

In the embodiment shown in FIG. 12, for any two of the first light-emitting units 11 which are adjacent to each other along the first direction F1, the first light-emitting element 111 in one of the first light-emitting units 11 is one of B1, B2, and B3, and the first light-emitting element 111 in the other of the first light-emitting units 11 is another one of B1, B2, and B3, that is, D₁ is the difference between the dominant wavelengths of two of B1, B2; since the dominant wavelengths of B1, B2 and B3 are not equal to each other, D₁ is greater than 0. A part of the first light-emitting units 11 and the first light-emitting units 11 which are adjacent to the part of the first light-emitting units 11 along the second direction F2 have the first light-emitting elements 111 of the same light-emitting color; as shown in FIG. 12, along the second direction F2, there are a plurality of pairs of B1 which are adjacent to each other, a plurality of pairs of B2 which are adjacent to each other, and a plurality of pairs of B3 which are adjacent to each other; for a pair of B1, a pair of B2, and a pair of B3 which are adjacent to each other, the corresponding D₂ is 0, so that D₁>D₂ is satisfied.

Referring to FIG. 13, FIG. 13 is a schematic view of an arrangement of first light-emitting elements in yet another display panel according to embodiments of the present application. Based on the above embodiments, in the embodiment shown in FIG. 13, c=3, one of the plurality of first light-emitting units 11 has one first light-emitting element 111 (that is, m=n=1), and one of the plurality of sub-display regions 12 has the plurality of first light-emitting units 11 in two rows and two columns. In this embodiment, the first direction F1 includes the row direction X and the column direction Y, the second direction F2 includes one diagonal direction, the first light-emitting elements 111 are blue light-emitting elements B, and the three types of blue light-emitting elements B which have different dominant wavelengths are B1, B2, and B3, respectively. The second direction F2 is the diagonal direction between the positive direction of the row direction X and the positive direction of the column direction Y which are shown in FIG. 13.

In the embodiment shown in FIG. 13, for any two first light-emitting units 11 which are adjacent to each other along the first direction F1, the first light-emitting element 111 in one of the first light-emitting units 11 is one of B1, B2, and B3, and the first light-emitting element 111 in the other of the first light-emitting units 11 is another one of B1, B2, and B3, that is, D₁ is the difference between the dominant wavelengths of two of B1, B2; since the dominant wavelengths of B1, B2 and B3 are not equal to each other, D₁ is greater than 0. A part of the first light-emitting units 11 and the first light-emitting units 11 which are adjacent to the part of the first light-emitting units 11 along the second direction F2 have the first light-emitting elements 111 of the same light-emitting color; as shown in FIG. 13, along the second direction F2, there are a plurality of pairs of B2 which are adjacent to each other; for the pairs of B2 which are adjacent to each other, the corresponding D₂ is 0, so that D₁>D₂ is satisfied.

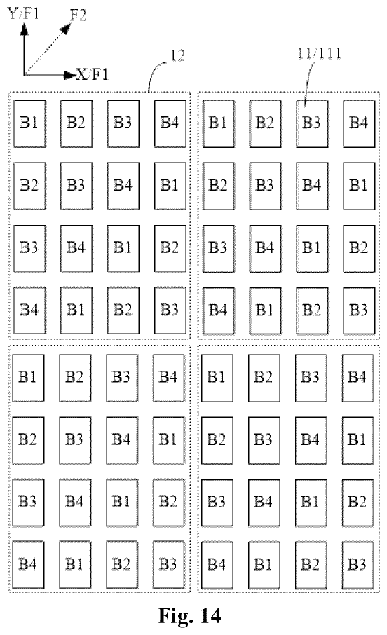

Referring to FIG. 14, FIG. 14 is a schematic view of an arrangement of first light-emitting elements in yet another display panel according to embodiments of the present application. Based on the above embodiments, in the embodiment shown in FIG. 14, c=4, one of the first light-emitting units 11 has one first light-emitting element 111 (that is, m=n=1), and one of the plurality of sub-display regions 12 has the first light-emitting units 11 in four rows and four columns. In this embodiment, the first direction F1 includes the row direction X and the column direction Y, the second direction F2 includes one diagonal direction, the first light-emitting elements 111 are blue light-emitting elements B, and the four types of blue light-emitting elements B which have different dominant wavelengths are B1, B2, B3, and B4, respectively. The second direction F2 is the diagonal direction between the positive direction of the row direction X and the positive direction of the column direction Y which are shown in FIG. 14.

In the embodiment shown in FIG. 14, for any two first light-emitting units 11 which are adjacent to each other along the first direction F1, the first light-emitting element 111 in one of the first light-emitting units 11 is one of B1, B2, B3, and B4, and the first light-emitting element 111 in the other of the first light-emitting units 11 is another one of B1, B2, B3, and B4, that is, D₁ is the difference between the dominant wavelengths of two of B1, B2, B3, and B4; since the dominant wavelengths of B1, B2, and B3 are not equal to each other, D₁ is greater than 0. A part of the first light-emitting units 11 and the first light-emitting units 11 which are adjacent to the part of the first light-emitting units 11 along the second direction F2 have the first light-emitting elements 111 of the same light-emitting color; as shown in FIG. 14, along the second direction F2, there are a plurality of pairs of B1 which are adjacent to each other, a plurality of pairs of B2 which are adjacent to each other, a plurality of pairs of B3 which are adjacent to each other, and a plurality of pairs of B4 which are adjacent to each other; for a pair of B1, a pair of B2, a pair of B3, and a pair of B4 which are adjacent to each other, the corresponding D₂ is 0, so that D₁>D₂ is satisfied.

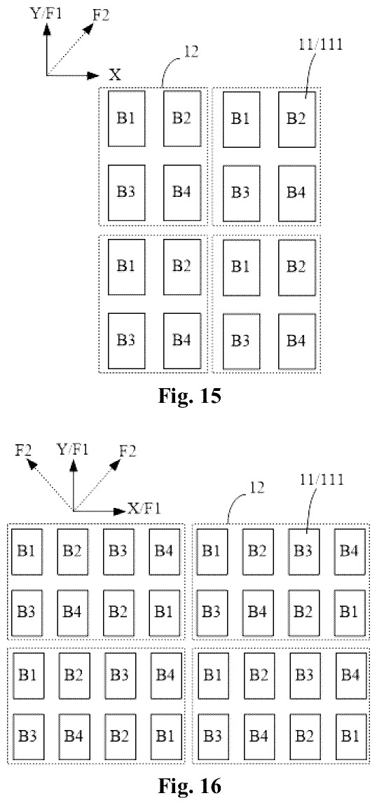

Referring to FIG. 15, FIG. 15 is a schematic view of an arrangement of first light-emitting elements in yet another display panel according to embodiments of the present application. Based on the above embodiments, in the embodiment shown in FIG. 15, c=4, one of the first light-emitting units 11 has one first light-emitting element 111 (that is, m=n=1), and one of the plurality of sub-display regions 12 has the first light-emitting units 11 in two rows and two columns. In this embodiment, the first direction F1 includes the column direction Y, the second direction F2 includes one diagonal direction, the first light-emitting elements 111 are blue light-emitting elements B, and the four types of blue light-emitting elements B which have different dominant wavelengths are B1, B2, B3, and B4, respectively. The second direction F2 is the diagonal direction between the positive direction of the row direction X and the positive direction of the column direction Y which are shown in FIG. 15.

In the embodiment shown in FIG. 15, the difference between the dominant wavelengths of B1 and B3 and the difference between the dominant wavelengths of B2 and B4 are both greater than the difference between the dominant wavelengths of B2 and B3. Along the first direction F1, there are B1 and B3 which are adjacent to each other and B2 and B4 which are adjacent to each other, so that D₁ is the difference between the dominant wavelengths of B1 and B3 or the difference between the dominant wavelengths of B2 and B4. Along the second direction F2, there are B2 and B3 which are adjacent to each other, and D₂ is the difference between the dominant wavelengths of B2 and B3. Therefore, D₁>D₂ is satisfied in this embodiment.

Referring to FIG. 16, FIG. 16 is a schematic view of an arrangement of first light-emitting elements in yet another display panel according to embodiments of the present application. Based on the above embodiments, in the embodiment shown in FIG. 16, c=4, one of the first light-emitting units 11 has one first light-emitting element 111 (that is, m=n=1), and one of the plurality of sub-display regions 12 has the first light-emitting units 11 in two rows and four columns. In this embodiment, the first direction F1 includes the row direction X and the column direction Y, the second direction F2 includes two diagonal directions, the first light-emitting elements 111 are blue light-emitting elements B, and the four types of blue light-emitting elements B which have different dominant wavelengths are B1, B2, B3, and B4, respectively.

In the embodiment shown in FIG. 16, the difference between the dominant wavelengths of B1 and B3, the difference between the dominant wavelengths of B1 and B4, and the difference between the dominant wavelengths of B2 and B4 are all great than the difference between the dominant wavelengths of B2 and B3, and are all greater than the difference between the dominant wavelengths of B3 and B4. Along the first direction F1, there are B1 and B3 which are adjacent to each other, B2 and B4 which are adjacent to each other, and B1 and B4 which are adjacent to each other, so that D₁ is the difference between the dominant wavelengths of B1 and B3, or the difference between the dominant wavelengths of B2 and B4, or the difference between the dominant wavelengths of B1 and B4. Along the second direction F2, there are B2 which are adjacent to each other, B2 and B3 which are adjacent to each other, and B3 and B4 which are adjacent to each other, so that D₂ is the difference between the dominant wavelengths of B2 and B2, or the difference between the dominant wavelengths of B2 and B3, or the difference between the dominant wavelengths of B3 and B4. Therefore, D₁>D₂ is satisfied in this embodiment.

In an implementation of an embodiment of the present application, under a condition that c is greater than 2, m=n=1. As shown in FIG. 11 to FIG. 13, under a condition that c=3, m=n=1. As shown in FIG. 14 to FIG. 16, under a condition that c=4, m=n=1. In this embodiment, the situation in which the plurality of sub-display regions 12 have a relatively great number of first light-emitting elements 111 and the situation in which the compensation effect between the first light-emitting elements 111 which have different dominant wavelengths is affected since the single sub-display region 12 occupies a relatively great area in the display panel may be prevented.

If c>2, c may be set to be 3 or 4. If c>4, the plurality of sub-display regions 12 have a relatively great number of first light-emitting elements 111, and the compensation effect between the first light-emitting elements 111 which have different dominant wavelengths is affected since the single sub-display region 12 occupies a relatively great area in the display panel.

In an implementation of an embodiment of the present application, under a condition that c is greater than 2, in the same sub-display region 12, along the first direction F1, the dominant wavelengths of c consecutive first light-emitting units 11 are different from each other. In this embodiment, as shown in FIG. 11 and FIG. 14, for the same sub-display region 12, along the first direction F1, the dominant wavelengths of c consecutive first light-emitting units 11 in rows and columns may be set to be different from each other. Alternatively, as shown in FIG. 12 and FIG. 16, for the same sub-display region 12, along the first direction F1, the dominant wavelengths of c consecutive first light-emitting units 11 in rows or columns are different from each other. In this embodiment, the display complementarity may be achieved between the c first light-emitting units 11 which are consecutively arranged along the first direction F1 and have dominant wavelengths different from each other.

Optionally, in the display panel, the dominant wavelengths of any consecutive c first light-emitting units 11 in rows and columns may be set to be different from each other. In this way, c types of the plurality of first light-emitting units 11 which have different dominant wavelengths may be uniformly and orderly distributed in the display panel, and the desired display complementarity may be achieved between the plurality of first light-emitting units 11 which have dominant wavelengths different from each other.

In an implementation of an embodiment of the present application, under a condition that c is greater than 2, in the same sub-display region 12, along the first direction F1, the difference between the dominant wavelengths of two first light-emitting units 11 which are adjacent to each other is the first difference D₁; along the second direction F2, the difference between the dominant wavelengths of two first light-emitting units 11 which are adjacent to each other is the second difference D₂. In this way, in the same sub-display region 12, the display complementarity may be achieved by the first light-emitting units 11 which have the first difference D₁ and the first light-emitting units 11 which have the second difference D₂, and the display complementarity may be achieved between the first light-emitting units 11 which have different dominant wavelengths in the same sub-display region 12 to increase the display uniformity.

Under a condition that c is greater than 2, as shown in FIG. 13 and FIG. 15, in the same row of first light-emitting units 11, two types of first light-emitting units 11 which have dominant wavelengths different from each other may be alternately arranged in sequence; in the same row of first light-emitting units 11, two types of first light-emitting units 11 which have dominant wavelengths different from each other are alternately arranged in sequence. In this embodiment, in rows and columns, two types of first light-emitting units 11 which have dominant wavelengths different from each other are alternately arranged in sequence; and in the rows and the columns, the display complementary may be achieved based on two types of first light-emitting units 11 which have dominant wavelengths different from each other to increase the display uniformity.

Under a condition that c is greater than 2, as shown in FIG. 12 and FIG. 16, along one of the row direction X and the column direction Y, two types of first light-emitting units 11 which have dominant wavelengths different from each other may be alternately arranged in sequence; along the other of the row direction X and the column direction Y, the dominant wavelengths of c consecutive first light-emitting units 11 are different from each other. In this embodiment, along one of the row direction X and the column direction Y, the display complementarity is achieved based on two types of first light-emitting units 11 which have dominant wavelengths different from each other, and along the other of the row direction X and the column direction Y, the display complementarity is achieved based on c types of first light-emitting units 11 which have dominant wavelengths different from each other to increase the display uniformity.

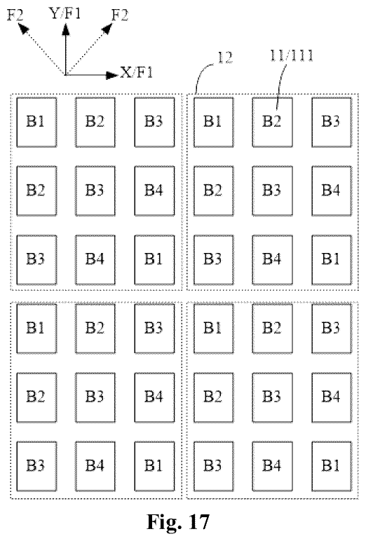

Referring to FIG. 17, FIG. 17 is a schematic view of an arrangement of first light-emitting elements in yet another display panel according to embodiments of the present application. Based on the above embodiments, in the embodiment shown in FIG. 17, c=4, one of the first light-emitting units 11 has one first light-emitting element 111 (that is, m=n=1), and one of the plurality of sub-display regions 12 has the first light-emitting units 11 in three rows and three columns. In this embodiment, the first direction F1 includes the row direction X and the column direction Y, the second direction F2 includes two diagonal directions, the first light-emitting elements 111 are blue light-emitting elements B, and the four types of blue light-emitting elements B which have different dominant wavelengths are B1, B2, B3, and B4, respectively.

In the embodiment shown in FIG. 17, for any two first light-emitting units 11 which are adjacent to each other along the first direction F1, the first light-emitting element 111 in one of the first light-emitting units 11 is one of B1, B2, B3, and B4, and the first light-emitting element 111 in the other of the first light-emitting units 11 is another one of B1, B2, B3, and B4, that is, D₁ is the difference between the dominant wavelengths of two of B1, B2, B3, and B4; since the dominant wavelengths of B1, B2, and B3 are not equal to each other, D₁ is greater than 0. A part of the first light-emitting units 11 and the first light-emitting units 11 which are adjacent to the part of the first light-emitting units 11 along the second direction F2 have the first light-emitting elements 111 of the same light-emitting color; as shown in FIG. 14, along the second direction F2, there are a plurality of pairs of B1 which are adjacent to each other, a plurality of pairs of B2 which are adjacent to each other, a plurality of pairs of B3 which are adjacent to each other, and a plurality of pairs of B4 which are adjacent to each other; for a pair of B1, a pair of B2, a pair of B3, and a pair of B4 which are adjacent to each other, the corresponding D₂ is 0, so that D₁>D₂ is satisfied.

In an implementation of an embodiment of the present application, as shown in FIG. 17, under a condition that c is greater than 3, in the same sub-display region 12, along the first direction F1, the dominant wavelengths of three consecutive first light-emitting units 11 are different from each other; in the same row of first light-emitting units 11, three types of first light-emitting units 11 which have dominant wavelengths different from each other are alternately arranged; in the same row of first light-emitting units 11, three types of first light-emitting units 11 which have dominant wavelengths different from each other are alternately arranged. In this way, in rows and columns, three types of first light-emitting units 11 which have different dominant wavelengths are alternately arranged, so that the compensation distance between a plurality of consecutive first light-emitting units 11 which have different dominant wavelengths in one row or one column may be reduced to increase the compensation display effect.

Optionally, the first difference is greater than 2 nm, and the second difference is not greater than 2 nm, that is, D₁>2 nm, and D₂≤2 nm. In this way, the first light-emitting units 11 which have the dominant wavelength difference great than 2 nm and the first light-emitting units 11 which have the dominant wavelength difference not great than 2 nm may achieve the display complementarity, and under a condition that the display panel includes the plurality of first light-emitting units 11 which have different dominant wavelengths, the display uniformity may be increased.

In an implementation of an embodiment of the present application, the second difference is not great than 1 nm, that is, D₂≤1 nm, so that the difference between the dominant wavelengths of the first light-emitting units 11 which are adjacent to each other along the second direction F2 may be relatively small, and the difference between the dominant wavelengths of two first light-emitting units 11 which are adjacent to each other along the first direction F1 may be better compensated, and thus the display panel has the desired display uniformity.

Optionally, the first light-emitting elements 111 are blue light-emitting elements B. Taking for the example that the light-emitting elements in the display panel are the Micro LEDs, in the red light-emitting elements R, the green light-emitting elements G, and the blue light-emitting elements B, under a condition that the difference between the dominant wavelengths of two light-emitting elements of the same light-emitting color is not less than 1 nm, since the just noticeable color difference (JNCD) between the blue light-emitting elements B is 1.9, the JNCD between the green light-emitting elements G is 0.7, and the JNCD between the red light-emitting elements R is 1.6. It may be seen that under a condition that the difference between the dominant wavelengths is the same, the color difference between two blue light-emitting elements B is relatively great; in order to better increase the display uniformity of the display panel, the first light-emitting elements 111 are set to be blue light-emitting elements B.

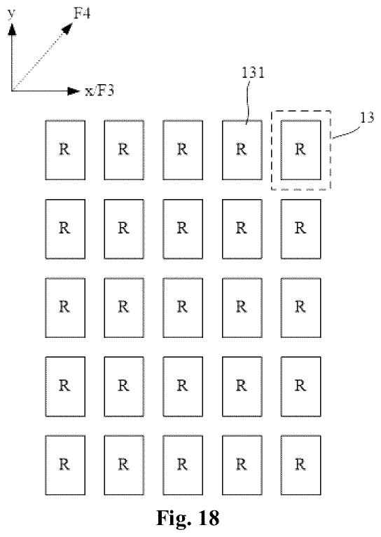

Referring to FIG. 18, FIG. 18 is a schematic view of an arrangement of first light-emitting elements in yet another display panel according to embodiments of the present application. Based on the above embodiments, in the display panel shown in FIG. 18, the display layer further includes a plurality of second light-emitting units 13 which are arranged in an array, and one of the plurality of second light-emitting units 13 includes at least one second light-emitting element 131 which emits light of the second color; and the dominant wavelengths of the plurality of second light-emitting units 13 satisfy: |D₃−D₄|>0, where D₃ represents the third difference between the dominant wavelengths of the second light-emitting elements 131 in two of the plurality of second light-emitting units 13 which are adjacent to each other along the third direction F3, the third direction F3 includes at least one of the row direction or the column direction of the array where the plurality of second light-emitting units 13 are located; and D₄ represents the fourth difference between the dominant wavelengths of the second light-emitting elements 131 in two of the plurality of second light-emitting units 13 which are adjacent to each other along the fourth direction F4, the angle between the fourth direction F4 and the third direction F3 is greater than 0° and less than 90°. In this embodiment, the display complementarity effect of the second light-emitting elements 131 which have different dominant wavelengths may be achieved while the display complementarity effect of the first light-emitting elements 111 which have different dominant wavelengths is achieved, so the display uniformity of the display panel may be better increased.

The plane where the first direction F1 intersects with the second direction F2 is coplanar with the plane where the third direction F3 intersects with the fourth direction F4, and the planes are both parallel to the plane where the display layer is located.

In the embodiments of the present application, the display layer includes at least one of the plurality of second light-emitting units 13; along the third direction F3, the difference between the dominant wavelength of the at least one of the plurality of second light-emitting units 13 and the dominant wavelengths of other ones of the plurality of second light-emitting units 13 is the third difference; and along the fourth direction F4, the difference between the dominant wavelength of the at least one of the plurality of second light-emitting units 13 and the dominant wavelengths of other ones of the plurality of second light-emitting units 13 is the fourth difference. In this way, the display complementarity may be achieved by the plurality of second light-emitting units 13 which have the difference between different dominant wavelengths to increase the display uniformity.

The row direction x of the plurality of first light-emitting units 11 may be the same as the row direction x of the plurality of second light-emitting units 13, and the column direction y of the plurality of first light-emitting units 11 may be same as the column direction y of the plurality of second light-emitting units 13; if the real arrangement may be used in the red light-emitting elements R, the green light-emitting elements G, the blue light-emitting elements B in the display layer, the red light-emitting elements R, the green light-emitting elements G, and the blue light-emitting elements B are alternately arranged in the same row, the light-emitting colors of any three consecutive light-emitting elements are different from each other, and the light-emitting colors of the light-emitting elements in the same column are the same.

The row direction x of the plurality of first light-emitting units 11 may be different from the row direction x of the plurality of second light-emitting units 13, the column direction y of the plurality of first light-emitting units 11 may be different from the column direction y of the plurality of second light-emitting units 13, and the pentile arrangement, the diamond arrangement, or the delta arrangement may be used in the red light-emitting elements R, the green light-emitting elements G, and the blue light-emitting elements B in the display layer.

In the embodiments of the present application, the arrangement of the light-emitting elements may be set as needed, and the arrangement of the light-emitting elements in the display layer is not limited by the embodiments of the present application.

In the embodiment shown in FIG. 18, the example in which the second light-emitting elements 131 are red light-emitting elements R is given for illustration. In the embodiments of the present application, the first light-emitting elements 111 are not limited to be the blue light-emitting element B, and the second light-emitting elements 131 are not limited to be the red light-emitting element R; the first light-emitting elements 111 may be any one of the red light-emitting element R, the green light-emitting element G, and the blue light-emitting element B, and the second light-emitting elements 1311 may be other ones of the red light-emitting element R, the green light-emitting element G, and the blue light-emitting element B.

In an implementation of an embodiment of the present application, one of the plurality of second light-emitting units 13 includes one second light-emitting element 131; or one of the second light-emitting units 13 includes q second light-emitting elements 131, q is a positive integer greater than 1, and the difference between the dominant wavelengths of two second light-emitting elements 131 in the same second light-emitting unit 13 is not greater than the third threshold, D₃>D₄, and the third threshold is less than or equal to D₄.

Optionally, if a plurality of second light-emitting elements 131 are included in the same second light-emitting unit 13, the difference between the dominant wavelength of one of the plurality of second light-emitting elements 131 and the dominant wavelengths of other ones of the plurality of second light-emitting elements 131 may be set to be the third threshold.

If one of the plurality of second light-emitting units 13 includes one second light-emitting element 131, in the second light-emitting element array, the difference between the dominant wavelengths of two second light-emitting elements 131 which are adjacent to each other along the third direction F3 is D₃, and the difference between the dominant wavelengths of two second light-emitting elements 131 which are adjacent to each other along the fourth direction F4 is D₄. With the unequal differences in the dominant wavelengths, the complementarity in the display effect is achieved between the two second light-emitting elements 131 which are adjacent to each other along the third direction F3 and the two second light-emitting elements 131 which are adjacent to each other along the fourth direction F4 to reduce the problem of non-uniform display of the display panel which is caused by the display difference in the second light-emitting elements 131.

If one of the plurality of second light-emitting units 13 includes p second light-emitting elements 131, the second light-emitting element array is divided into a plurality of sub-arrays. One of the plurality of sub-arrays is used as one second light-emitting unit 131 which includes q second light-emitting elements 131. The q second light-emitting elements 131 in the same second light-emitting unit 13 are arranged in e rows and f columns, q=e*f, e and f are both positive integers, and at least one of e or f is greater than 1. Since the third threshold is less than or equal to D₄, the q second light-emitting elements 131 in the same second light-emitting unit 13 have equal or approximate dominant wavelengths, which may facilitate the scheme design in which complementarity in the dominant wavelengths of the q second light-emitting elements 131 in the same second light-emitting unit 13 as a whole and the dominant wavelengths of q second light-emitting elements 131 in one of other second light-emitting units 13 may be achieved.

The reference may be made to the arrangement of the plurality of first light-emitting units 11 in the above embodiments for that of the plurality of second light-emitting units 13, which is not repeated in the embodiments of the present application.

Optionally, the first light-emitting elements 111 are blue light-emitting elements B; and the second light-emitting elements 131 are green light-emitting elements G or red light-emitting elements R. Specifically, the second light-emitting elements 131 may be red light-emitting elements R. As described above, with the unit dominant wavelength difference (1 nm), the JNCD of the blue light-emitting elements B, the JNCD of the red light-emitting elements R, and the JNCD of the green light-emitting elements G are reduced in sequence; the first light-emitting elements 111 are provided to be the blue light-emitting elements B, and the second light-emitting elements 131 are provided to be the red light-emitting elements R, so that the display compensation may be achieved for two types of light-emitting elements which have a relatively great color difference in the display panel to better increase the display uniformity of the display panel.

In the embodiments of the present application, the first difference is greater than the second difference, and the third difference is greater than the fourth difference, that is, D₁>D₂, and D₃>D₄. In this way, complementarity in the difference between the dominant wavelengths which correspond to the first light-emitting units 11 which are adjacent to each other along the first direction F1 and the difference between the dominant wavelengths which correspond to the first light-emitting units 11 which are adjacent to each other along the second direction F2 may be achieved, and complementarity in the difference between the dominant wavelengths which correspond to the second light-emitting units 13 which are adjacent to each other along the third direction F3 and the difference between the dominant wavelengths which correspond to the second light-emitting units 13 which are adjacent to each other along the fourth direction F4 may be achieved, so as to increase the entire display uniformity of the display panel.

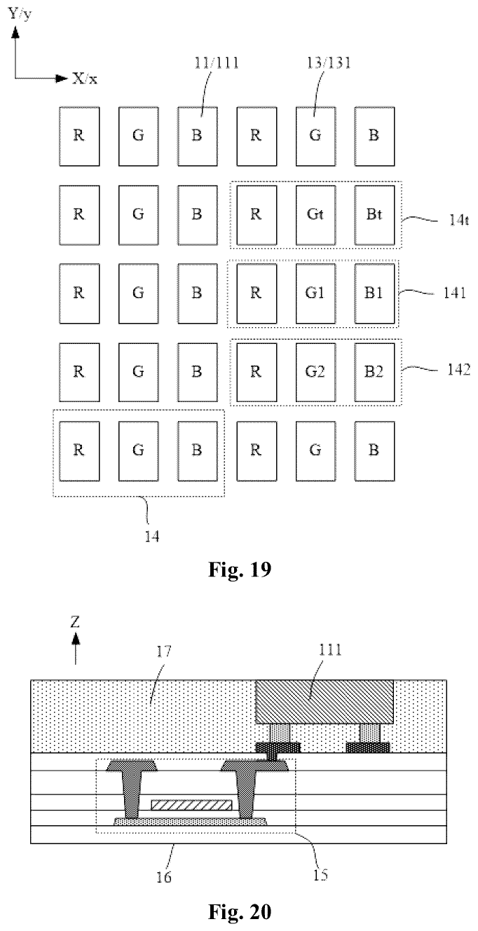

Referring to FIG. 19, FIG. 19 is a schematic view of an arrangement of first light-emitting elements in yet another display panel according to embodiments of the present application. Based on the above embodiments, in the display panel shown in FIG. 19, the display layer includes c types of first light-emitting elements 111 which have dominant wavelengths different from each other and c types of second light-emitting elements 131 which have dominant wavelengths different from each other, and c is a positive integer greater than 1; in FIG. 19, the example in which c=2 is given for illustration, and the display panel includes two types of first light-emitting elements 111 which have different dominant wavelengths and two types of second light-emitting elements 131 which have different dominant wavelengths. Taking for the example that the first light-emitting elements 111 are blue light-emitting elements B, two types of first light-emitting elements 111 which have different dominant wavelengths are B1 and B2, respectively; taking for the example that the second light-emitting elements 131 are green light-emitting elements G, two types of second light-emitting elements 131 which have different dominant wavelengths are G1 and G2, respectively.

The display layer includes a plurality of pixel units 14, one of the plurality of pixel units 14 includes the first light-emitting element 111 which has one type of dominant wavelength and the second light-emitting element 131 which has one type of dominant wavelength. In FIG. 19, the example in which the real arrangement of three types of light-emitting elements of different light-emitting colors in the display panel is given for illustration; under this condition, the array row directions of three types of light-emitting elements of different colors are the same, and the array column directions of three types of light-emitting elements of different colors are the same. One of the plurality of pixel units 14 includes three light-emitting elements of different colors, that is, the red light-emitting element R, the green light-emitting element G, and the blue light-emitting element B which are arranged in sequence along the array row direction.

As shown in FIG. 19, the plurality of pixel units 14 in the display layer include the first pixel unit 141 and the second pixel unit 142, the dominant wavelength of the first light-emitting element 111 in the first pixel unit 141 is greater than the dominant wavelength of the first light-emitting element 111 in the second pixel unit 142, and the dominant wavelength of the second light-emitting element 131 in the first pixel unit 141 is greater than the dominant wavelength of the second light-emitting element 131 in the second pixel unit 142. The dominant wavelength of B1 is set to be greater than the dominant wavelength of B2, and the dominant wavelength of G1 is set to be greater than the dominant wavelength of G2, for any pixel unit 14, if the first light-emitting element 111 is B1, the second light-emitting element 131 is G1, and if the first light-emitting element 111 is B2, the second light-emitting element 131 is G2. In this embodiment, the dominant wavelengths of the first light-emitting element 111 and the second light-emitting element 131 in one of the plurality of pixel units 14 may be positively correlated, the first light-emitting element 111 which has a greater dominant wavelength and the second light-emitting element 131 which has a greater dominant wavelength may form the first pixel unit 141, and the first light-emitting element 111 which has a smaller dominant wavelength and the second light-emitting element 131 which has a smaller dominant wavelength may form the second pixel unit 142, so that the dominant wavelengths of the first light-emitting element 111 and the second light-emitting element 131 in each of the plurality of pixel units 14 may be matched, and the color cast of the display panel may be reduced, increasing the image display quality.

The dominant wavelengths of c types of first light-emitting elements 111 which have dominant wavelengths different from each other are set to be λ_{B1} to ∥_{Bc} in sequence, and λ_{B1} to λ_{Bc} to are increased in sequence; and the dominant wavelengths of c types of second light-emitting elements 131 which have dominant wavelengths different from each other are set to be λ_{G1} to λ_{Gc} in sequence, and λ_{G1} to λ_{Gc} are increased in sequence. The display layer includes the first pixel unit 141 to the c-th pixel unit 14c; for a positive integer t not great than c, in the t-th pixel unit 14t, the dominant wavelength of the first light-emitting element 111 is λ_{Bt}, and the dominant wavelength of the second light-emitting element 131 is A_{Gt}. Taking for the example that the first light-emitting elements 111 are blue light-emitting elements B and the second light-emitting elements 131 are green light-emitting elements G, c types of first light-emitting elements 111 which have dominant wavelengths different from each other are B1 to Bc in sequence, and the dominant wavelengths of B1 to Bc are increased in sequence; c types of second light-emitting elements 131 which have dominant wavelengths different from each other are G1 to Gc in sequence, and the dominant wavelengths of G1 to Gc are increased in sequence; and in the t-th pixel unit 14t, the first light-emitting element 111 is Bt, and the second light-emitting element 131 is Gt.

Referring to FIG. 20, FIG. 20 is a cross-sectional view of a display panel according to embodiments of the present application. Based on the above embodiments, as shown in FIG. 20, the first light-emitting element 111 is connected to the pixel circuit 15, and the pixel circuit 15 is configured to control the first light-emitting element 111 which is connected thereto to display an image. The display layer includes c types of first light-emitting elements 111 which have dominant wavelengths different from each other, and c is a positive integer greater than 1; if the same gray scale is displayed, in c types of first light-emitting elements 111 which have dominant wavelengths different from each other, the data voltages which are provided by the pixel circuits 15 connected to at least two types of the first light-emitting elements 111 are different from each other. In FIG. 20, the fifth direction Z is perpendicular to the plane where the display layer is located. In this embodiment, when displaying the same gray scale, the first light-emitting elements 111 which have different dominant wavelengths emit light and display based on different data voltages, and may compensate for the display difference which is caused by the difference between the dominant wavelengths based on the difference in data voltages, further increasing the display uniformity.

The display panel has the base plate 16, and the TFT array is formed on the base plate 16 to form the pixel circuit 15. The first light-emitting element 111 is welded and fixed to the surface of each thin film transistor (TFT) array. In FIG. 20, for the sake of clarity of illustration, only one first light-emitting element 111 and one TFT in the pixel circuit 15 which is connected to the first light-emitting element 111 are shown. In order to avoid the display crosstalk between different light-emitting elements, the vinyl layer 17 which surrounds the side walls of the light-emitting element is provided on the surface of the TFT array.

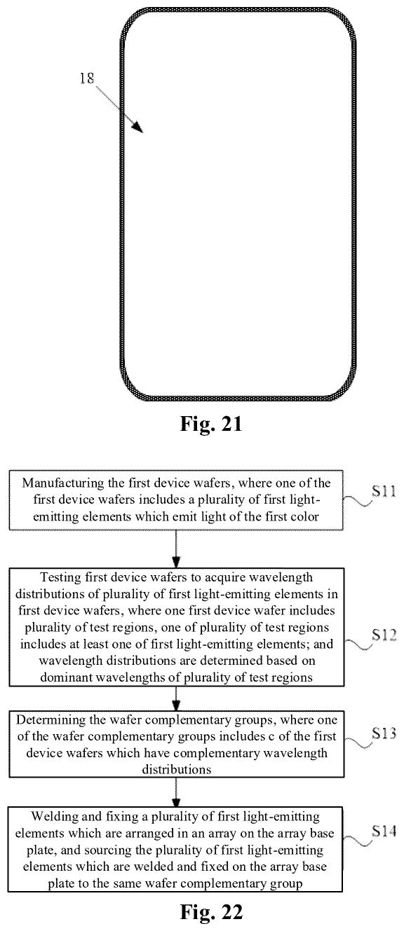

Based on the display panel according to the above embodiments, embodiments of the present application further provide an electronic device which may be as shown in FIG. 21.

Referring to FIG. 21, FIG. 21 is a schematic structural view of an electronic device according to embodiments of the present application, and the shown electronic device includes the display panel 18 which may be the display panel according to any one of the above embodiments.

Optionally, the electronic device may be, but is not limited to, a mobile phone, a tablet computer, a laptop computer, a smart wearable device, an AR device, a VR device, and the like.

In the embodiments of the present application, the electronic device includes the display panel according to the above embodiments; for the light-emitting elements of the same light-emitting color, the display complementarity may be achieved by the light-emitting elements which have different dominant wavelengths to increase the display uniformity and the image display quality.

Taking the method for manufacturing the Micro LED display panel as an example, in the conventional manufacturing method, for the Micro LEDs of the same light-emitting color, two transfer processes are generally required to complete the welding and binding of the Micro LEDs on the array base plate. Taking the blue Micro LEDs as an example, the conventional manufacturing method includes the following steps.

First, a plurality of blue Micro LEDs are manufactured on a wafer (such as a sapphire substrate).

Next, the blue Micro LEDs on the wafer are transferred to the first carrier base plate as a whole by the first transfer process.

Then, the blue Micro LEDs on the first carrier base plate are transferred to the second carrier base plate based on the arrangement of the light-emitting elements of various colors in the display panel by the second transfer process. Last, the light-emitting elements of various colors on the second carrier base plate are transferred to the array base plate for a plurality of times, and are welded and fixed to the pad on the array base plate to be electrically connected to the corresponding pixel circuits.

In the second transfer process, the blue Micro LEDs on the carrier base plate are transferred in blocks, and a plurality of blue Micro LEDs in the same block are transferred to the array base plate synchronously.

Since there is the difference in composition and thickness of film layers of blue Micro LEDs in different regions of the wafer in the manufacturing process, there is the difference in dominant wavelengths of blue Micro LEDs in different regions of the wafer. In the first transfer process, the blue Micro LEDs on the wafer are all transferred to the carrier base plate as a whole, so that the arrangement of the blue Micro LEDs relative to the wafer is not changed. Since there is the difference in dominant wavelengths of blue Micro LEDs in different regions of the wafer, the blue Micro LEDs may have a relatively great dominant wavelength jump at the boundaries between blocks during the second transfer, causing the non-uniform display at the boundaries between blocks in the display panel. As shown in FIG. 1, when the display panel displays the monochromatic blue image, there are stripes at the boundaries between blocks.

In order to solve the problem of non-uniform display of the display panel which is caused by the conventional manufacturing method, embodiments of the present application provide a method for manufacturing the display panel which is used for manufacturing the display panel according to any one the above embodiments and may be as shown in FIG. 22.

Referring to FIG. 22, FIG. 22 is a schematic flowchart of a method for manufacturing the display panel according to embodiments of the present application, and the method includes the following steps.
Step S11: manufacturing the first device wafers. One of the first device wafers includes a plurality of first light-emitting elements which emit light of the first color.
Step S12: testing the first device wafers to acquire the wavelength distributions of the plurality of first light-emitting elements in the first device wafers. One of the first device wafers includes a plurality of test regions, one of the plurality of test regions includes at least one of the first light-emitting elements; and the wavelength distributions are determined based on the dominant wavelengths of the plurality of test regions.
Step S13: determining the wafer complementary groups. One of the wafer complementary groups includes c of the first device wafers which have complementary wavelength distributions.
Step S14: welding and fixing a plurality of first light-emitting elements which are arranged in an array on the array base plate, and sourcing the plurality of first light-emitting elements which are welded and fixed on the array base plate to the same wafer complementary group.

The array base plate has a plurality of first light-emitting units which are arranged in an array; one of the plurality of first light-emitting units includes at least one first light-emitting element which emits light of the first color; and the dominant wavelengths of the plurality of first light-emitting units satisfy |D₁−D₂|>0, where D₁ represents the first difference between the dominant wavelengths of the first light-emitting elements in two of the plurality of first light-emitting units which are adjacent to each other along the first direction, and the first direction includes at least one of the row direction or the column direction of the array where the plurality of first light-emitting units are located; and D₂ represents the second difference between the dominant wavelengths of the first light-emitting elements in two of the plurality of first light-emitting units which are adjacent to each other along the second direction, the angle between the second direction and the first direction is greater than 0° and less than 90°.

In the conventional manufacturing method, the first light-emitting elements are often directly transferred to the display panel based on the arrangement of the first light-emitting elements on the wafer, causing the above problem of stripes between the blocks. In the embodiments of the present application, the wafer complementary groups may be determined based on the dominant wavelength distributions of the first device wafers, and c of the first device wafers which have complementary wavelength distributions in one of the wafer complementary groups may provide the first light-emitting elements which have one type of dominant wavelength, so that the plurality of first light-emitting units which are formed by the first light-emitting elements which have c types of dominant wavelengths satisfy |D₁−D₂|>0. In this way, the display complementarity may be achieved by the plurality of first light-emitting units 11 which have the difference between different dominant wavelengths to increase display uniformity.

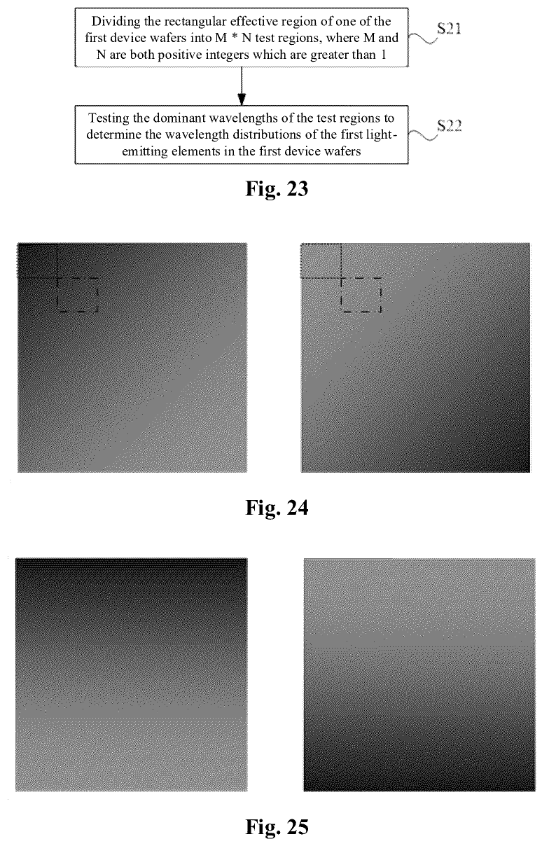

Referring to FIG. 23, FIG. 23 is a schematic flowchart of a method for testing a first device wafer according to embodiments of the present application, and the testing the first device wafer includes the following steps.
Step S21: dividing the rectangular effective region of one of the first device wafers into M*N test regions, where M and N are both positive integers which are greater than 1.

At the edge position of the wafer, the edge effect may cause relatively great quality defect in the first light-emitting elements. Therefore, in the process for manufacturing the display panel, the first light-emitting elements in the edge region are not often used, but the first light-emitting elements in the preset rectangular effective region are used for manufacturing the display panel.
Step S22: testing the dominant wavelengths of the test regions to determine the wavelength distributions of the first light-emitting elements in the first device wafers.

The first device wafers may be tested by the photoluminescence (PL) testing device and/or the electroluminescence (EL) testing device, and the dominant wavelength data of different test regions in the first device wafers may be obtained based on the test results, so that the wavelength distributions of the first light-emitting elements in the first device wafers may be acquired.

In the embodiment shown in FIG. 23, dividing one of the first device wafers into a plurality of test regions to test the dominant wavelengths of the first light-emitting elements may reduce the number of tests and the test data.

Referring to FIG. 24, FIG. 24 is a distribution view of a dominant wavelength of a first device wafer according to embodiments of the present application. In this embodiment, taking c=2 as an example, the wafer complementary group has two first device wafers which have complementary dominant wavelength distributions. In this embodiment, in the rectangular effective regions of the first device wafers, along the connection direction from the upper left corner to the lower right corner, the test data of the first device wafers on the left side indicates that the dominant wavelengths are decreased in sequence, and the test data of the first device wafers on the right side indicates that the dominant wavelengths are increased in sequence.

Referring to FIG. 25, FIG. 25 is a distribution view of a dominant wavelength of another first device wafer according to embodiments of the present application. In this embodiment, taking c=2 as an example, the wafer complementary group has two first device wafers which have complementary dominant wavelength distributions. In this embodiment, in the rectangular effective regions of the first device wafers, along the direction from the upper side to the lower side, the test data of the first device wafers on the left side indicates that the dominant wavelengths are decreased in sequence, and the test data of the first device wafers on the right side indicates that the dominant wavelengths are increased in sequence.

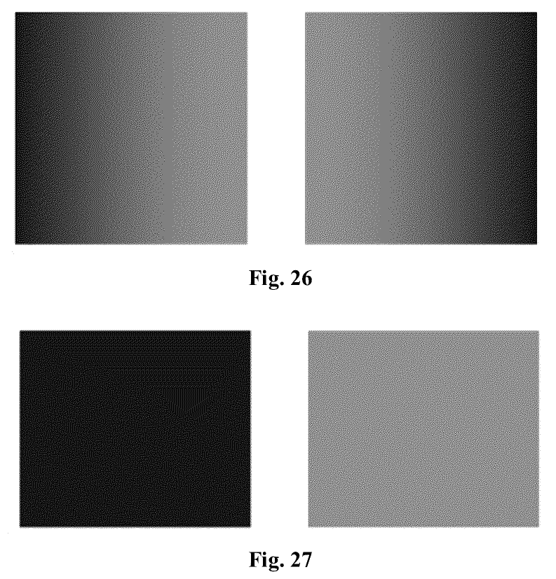

Referring to FIG. 26, FIG. 26 is a distribution view of a dominant wavelength of yet another first device wafer according to embodiments of the present application. In this embodiment, taking c=2 as an example, the wafer complementary group has two first device wafers which have complementary dominant wavelength distributions. In this embodiment, in the rectangular effective regions of the first device wafers, along the direction from the left side to the right side, the test data of the first device wafers on the left side indicates that the dominant wavelengths are decreased in sequence, and the test data of the first device wafers on the right side indicates that the dominant wavelengths are increased in sequence.

Referring to FIG. 27, FIG. 27 is a distribution view of a dominant wavelength of yet another first device wafer according to embodiments of the present application. In this embodiment, taking c=2 as an example, the wafer complementary group has two first device wafers which have complementary dominant wavelength distributions. In this embodiment, the test data of the first device wafers on the left side indicates that the overall dominant wavelengths are greater, and the test data of the first device wafers on the right side indicates that the overall dominant wavelengths are smaller.

The dominant wavelengths of the first device wafers may be determined from the electroluminescence or photoluminescence test data of the test regions of the first device wafers.

In any one of the embodiments in FIG. 24 to FIG. 27, for two first device wafers in the same wafer complementary group, if the blocks of one of the first device wafers have relatively small dominant wavelengths, blocks of the other of the first device wafers at the same positions have greater dominant wavelengths; in the same block, two first device wafers may provide the first light-emitting element which has one type of dominant wavelength; two types of first light-emitting elements which have different dominant wavelengths are arranged in the manner as the embodiments of the display panel, so that the display complementarity between the dominant wavelengths of the first light-emitting elements may be achieved; since the human eye cannot accurately recognize the color of the single first light-emitting unit and can only recognize the display complementarity effect of two types of first light-emitting elements which have different dominant wavelengths, the display uniformity may be increased in the recognition range of the human eye. If c=2, as shown in FIG. 3, in the embodiments of the present application, two first device wafers in the same wafer complementary group may provide the first light-emitting element which has one type of dominant wavelength. Taking for the example that the first light-emitting elements are blue light-emitting elements B, two first device wafers provide the blue light-emitting element B which have one type of wavelength; if the blue light-emitting element which is provided by one of the first device wafers is B1, and the blue light-emitting element which is provided by the other of the first device wafers is B2, B1 and B2 have different dominant wavelengths. Two types of blue light-emitting elements B are arranged in the display panel in the manner as shown in FIG. 3, so that at least part of the display region of display panel includes the first light-emitting units which are arranged in the manner as shown in FIG. 3.

Since B1 and B2 are sourced to different first device wafers, respectively, the dominant wavelengths of B1 and B2 are complementary and different, and the sum of the dominant wavelengths of B1 and B2 is a constant, in the second transfer process, the sum of the dominant wavelengths of two first device wafers which have complementary dominant wavelengths in the blocks is the same constant. Taking FIG. 24 as an example, in the block shown by the dashed box in FIG. 24, the dominant wavelength of one of two first device wafers is relatively great, the dominant wavelength of the other of two first device wafers is relatively small, and the sum of the dominant wavelengths of two first device wafers is a constant; in the block shown by the dot-dash box in FIG. 24, the dominant wavelength of one of two first device wafers is relatively great, the dominant wavelength of the other of two first device wafers is relatively small, and the sum of the dominant wavelengths of two first device wafers is a constant; and the sum of the dominant wavelengths of two first device wafers in the block shown by the dashed box is the same constant as the sum of the dominant wavelengths of two first device wafers in the block shown by the dot-dash box.

In the process for transferring the first light-emitting elements to the array base plate, as shown in FIG. 3, in nine first light-emitting elements which are arranged in three rows and three columns, if the first light-emitting element in the central region is B2, the first light-emitting elements which are adjacent to the first light-emitting element in the central region along the row direction X and the column direction Y may be B1, and the first light-emitting elements which are adjacent to the first light-emitting element in the central region along the diagonal directions may be B2. In this way, the difference between the dominant wavelength of the first light-emitting element B2 in the central region and the dominant wavelengths of the four first light-emitting elements which are adjacent to the first light-emitting element B2 in the central region along the first direction F1 (the row direction X and the column direction Y) is relatively great, and the difference is the difference between the dominant wavelengths of B1 and B2; the difference between the dominant wavelength of the first light-emitting element B2 in the central region and the dominant wavelengths of the four first light-emitting elements which are adjacent to the first light-emitting element B2 in the central region along the second direction F2 (two diagonal directions) is relatively small, and the difference is the difference between the dominant wavelengths of two B. As described above, the difference in the dominant wavelengths of the nine first light-emitting elements may be set to satisfy S₁≥2S₂, so that the complementarity in the display effect of two types of first light-emitting elements which have different dominant wavelengths in the display panel is achieved to reduce the problem of display non-uniformity of the display panel which is caused by the display difference in the first light-emitting elements.

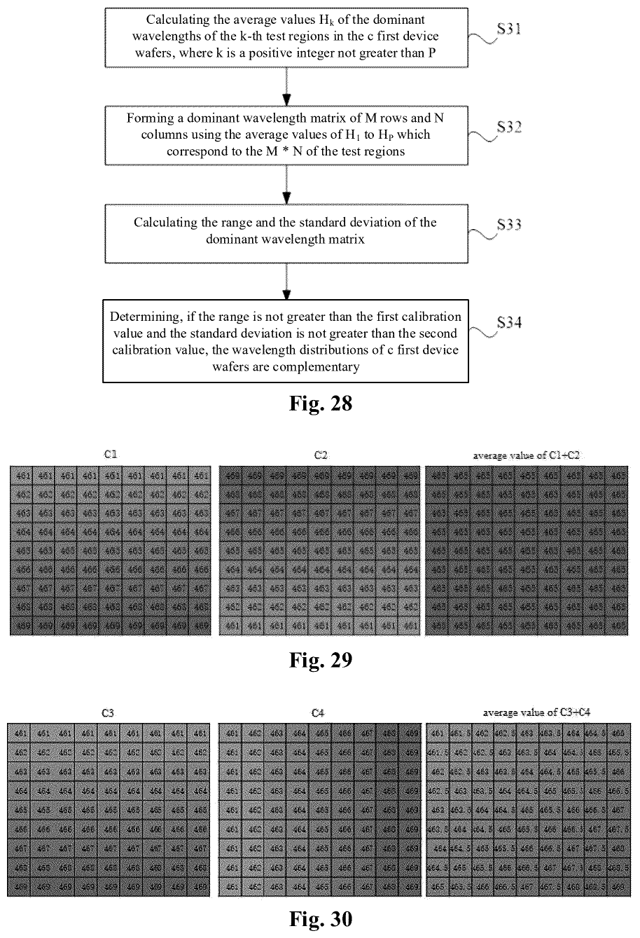

Referring to FIG. 28, FIG. 28 is a schematic flowchart of a method for determining a wafer complementary group according to embodiments of the present application. In the same device wafer, M*N test regions which are arranged in M rows and N columns are set to be the first test region to the P-th test region, and P=M*N; as shown in FIG. 28, the method for determining the wafer complementary group includes the following steps.
Step S31: calculating the average values Hₖ of the dominant wavelengths of the k-th test regions in the c first device wafers, where k is a positive integer not greater than P.
Step S32: forming a dominant wavelength matrix of M rows and N columns using the average values of H₁ to H_{P} which correspond to the M*N of the test regions.
Step S33: calculating the range and the standard deviation of the dominant wavelength matrix.
Step S34: determining, if the range is not greater than the first calibration value and the standard deviation is not greater than the second calibration value, the wavelength distributions of c first device wafers are complementary and belong to the same wafer complementary group; or, determining, if the range is greater than the first calibration value and/or the standard deviation is greater than the second calibration value, the wavelength distributions of c first device wafers are not complementary and do not belong to the same wafer complementary group.

In the embodiment shown in FIG. 28, based on the result of comparing the range and the standard deviation of the dominant wavelength matrix which is formed using the average values of the dominant wavelengths of the test regions to the corresponding calibration values, it may be determined whether the dominant wavelength distributions of a plurality of first device wafers are complementary and whether c first device wafers belong to the same wafer complementary group; and after testing of the dominant wavelengths of the first device wafers is completed, the wafer complementary group may be determined and grouped automatically by software.

The specific values of two calibration values may be set based on the accuracy requirements for the display compensation, and the smaller the calibration values are, the better the display compensation effect of the first light-emitting elements which have different dominant wavelengths in the display panel will be, and the better the display uniformity of the display panel will be. Optionally, the first calibration value is not greater than 4 nm and the second calibration value is not greater than 0.6 nm, and under a condition that the value range is satisfied, the wafer complementary group determined based on the first calibration value and the second calibration value may better achieve the display compensation for the first light-emitting elements which have different dominant wavelengths in the display panel.

Referring to FIG. 29, FIG. 29 is a schematic view of a calculation principle for determining a wafer complementary group according to embodiments of the present application. C1 in the left diagram and C2 in the middle diagram in FIG. 29 represent the dominant wavelength distributions of 9*9 test regions which are arranged in 9 rows and 9 columns in two first device wafers, each square represents one test region, and the data in the square represents the dominant wavelength value (unit nm). The right diagram in FIG. 29 represents the dominant wavelength matrix which is formed based on the average values of dominant wavelengths of the test regions of two first device wafers. In this embodiment, the range and the standard deviation are both 0, so under a condition that c=2, the dominant wavelength distributions of the two first device wafers are complementary.

Referring to FIG. 30, FIG. 30 is a schematic view of a calculation principle for determining a wafer complementary group according to embodiments of the present application. C3 in the left diagram and C4 in the middle diagram in FIG. 30 represent the dominant wavelength distributions of 9*9 test regions which are arranged in 9 rows and 9 columns in two first device wafers, each square represents one test region, and the data in the square represents the dominant wavelength value (unit nm). The right diagram in FIG. 30 represents the dominant wavelength matrix which is formed based on the average values of dominant wavelengths of the test regions of two first device wafers. In this embodiment, the range is 8, and the standard is 1.8, so under a condition that c=2, the dominant wavelength distributions of the two first device wafers are not complementary.

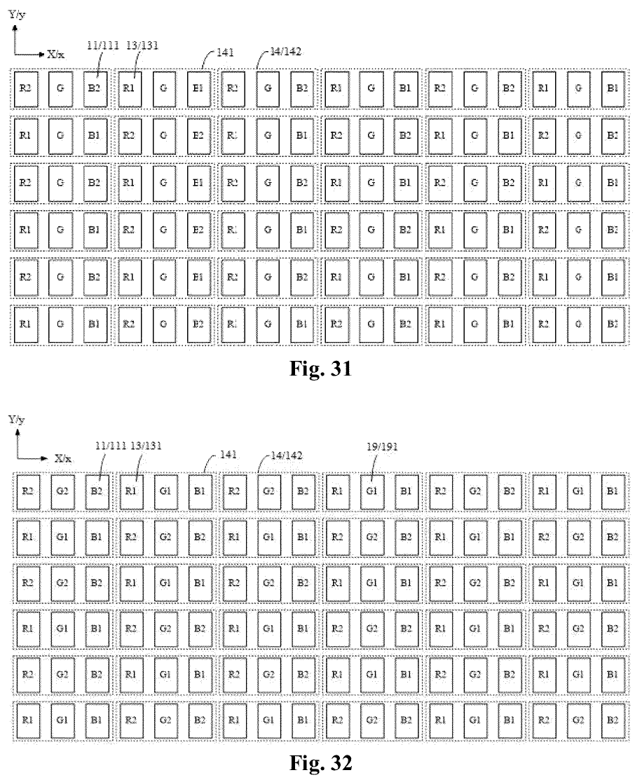

In an implementation of an embodiment of the present application, the method further includes: welding and fixing the second light-emitting elements which are arranged in an array on the array base plate based on the wafer complementary group of the second device wafer. Under this condition, the arrangement of the first light-emitting elements and the second light-emitting elements in the display panel may be as shown in FIG. 31.

Referring to FIG. 31, FIG. 31 is a schematic view of an arrangement of first light-emitting elements in yet another display panel according to embodiments of the present application. Based on the above embodiments, in the display panel shown in FIG. 31, c=2 is given for illustration. The display panel includes a plurality of pixel units 14, one of the plurality of pixel units 14 includes the first light-emitting element 111 which has one type of dominant wavelength and the second light-emitting element 131 which has one type of dominant wavelength; the plurality of pixel units 14 include the first pixel units 141 and the second pixel units 142, the dominant wavelength of the first light-emitting element 111 in one of the first pixel units 141 is greater than the dominant wavelength of the first light-emitting element 111 in one of the second pixel units 142, and the dominant wavelength of the second light-emitting element 131 in one of the first pixel units 141 is greater than the dominant wavelength of the second light-emitting element 131 in one of the second pixel units 142. In this embodiment, the second light-emitting elements 131 which have different dominant wavelengths in the display panel may achieve the display complementarity to better increase the display uniformity of the display panel. The method for determining the wafer complementary group of the second device wafer is the same as the method for determining the wafer complementary group of the first device wafer, which is not repeated by the embodiments of the present application.

In FIG. 31, taking for the example that the first light-emitting elements 111 are blue light-emitting elements B and the second light-emitting elements 131 are red light-emitting elements R, the first light-emitting elements 111 which have two types of dominant wavelengths are B1 and B2, respectively, and the second light-emitting elements 131 which have two types of dominant wavelengths are R1 and R2, respectively; the dominant wavelength of B1 may be set to be less than the dominant wavelength of B2, and the dominant wavelength of R1 may be set to be less than the dominant wavelength of R2.

For one non-edge B1, four first light-emitting elements 111 which are adjacent to the one non-edge B1 along the row direction and the column direction are all B2, and four first light-emitting elements 111 which are adjacent to the one non-edge B1 along the diagonal directions are all B1. For one non-edge B2, four first light-emitting elements 111 which are adjacent to the one non-edge B2 along the row direction and the column direction are all B1, and four first light-emitting elements 111 which are adjacent to the one non-edge B2 along the diagonal directions are all B2.

For one non-edge R1, four first light-emitting elements 111 which are adjacent to the one non-edge R1 along the row direction and the column direction are all R2, and four first light-emitting elements 111 which are adjacent to the one non-edge R1 along the diagonal directions are all R1. For one non-edge R2, four first light-emitting elements 111 which are adjacent to the one non-edge R2 along the row direction and the column direction are all R1, and four first light-emitting elements 111 which are adjacent to the one non-edge R2 along the diagonal directions are all R2.

Referring to FIG. 32, FIG. 32 is a schematic view of an arrangement of first light-emitting elements in yet another display panel according to embodiments of the present application. Based on the embodiment shown in FIG. 31, the display panel shown in FIG. 32 further includes the third light-emitting units 19, one of the third light-emitting units 19 includes at least one third light-emitting element 191 for emitting light of the third color. In FIG. 32, the example in which one of the light-emitting units includes the light-emitting element is given for illustration. Under this condition, the method further includes: welding and fixing the third light-emitting elements 191 which are arranged in an array on the array base plate based on the wafer complementary group of the third device wafer.

The method for determining the wafer complementary group of the third device wafer is the same as the method for determining the wafer complementary group of the first device wafer, which is not repeated by the embodiments of the present application.

As shown in FIG. 32, one of the plurality of pixel units 14 further includes the third light-emitting element 191 which has one type of dominant wavelength. The dominant wavelength of the third light-emitting element 191 in one of the first pixel units 141 is greater than the dominant wavelength of the third light-emitting element 191 in one of the second pixel units 142. In this embodiment, the third light-emitting elements 191 which have different dominant wavelengths in the display panel may achieve the display complementarity to better increase the display uniformity of the display panel.

Taking for the example that the third light-emitting elements 191 are green light-emitting elements G, the third light-emitting elements 191 which have two types of dominant wavelengths are G1 and G2, respectively, and the dominant wavelength of G1 may be set to be less than the dominant wavelength of G2. For one non-edge G1, four third light-emitting elements 191 which are adjacent to the one non-edge G1 along the row direction and the column direction are all G2, and four third light-emitting elements 191 which are adjacent to the one non-edge G1 along the diagonal directions are all G1. For one non-edge G2, four third light-emitting elements 191 which are adjacent to the one non-edge G2 along the row direction and the column direction are all G1, and four third light-emitting elements 191 which are adjacent to the one non-edge G2 along the diagonal directions are all G2. Under a condition that the technical solution of the embodiments of the present application are used for the display complementarity of the first light-emitting elements 111 which have different dominant wavelengths, the display complementarity may be achieved for the first light-emitting elements 111 in the part of the display region of the display panel, or the display complementarity may be achieved for the first light-emitting elements 111 in the entire display region.

Under a condition that the technical solution of the embodiments of the present application are used for the display complementarity of the second light-emitting elements 131 which have different dominant wavelengths, the display complementarity may be achieved for the second light-emitting elements 131 in the part of the display region of the display panel, or the display complementarity may be achieved for the second light-emitting elements 131 in the entire display region.

Under a condition that the technical solution of the embodiments of the present application are used for the display complementarity of the third light-emitting elements 191 which have different dominant wavelengths, the display complementarity may be achieved for the third light-emitting elements 191 in the part of the display region of the display panel, or the display complementarity may be achieved for third light-emitting elements 191 in the entire display region.

The principle for transferring the first light-emitting elements will be further described below with reference to the drawings.

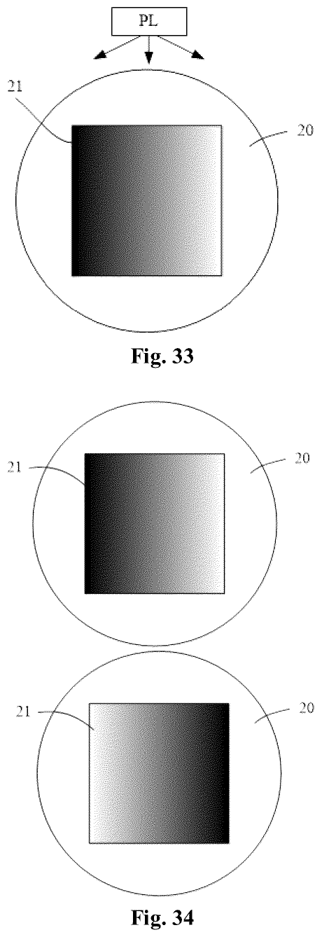

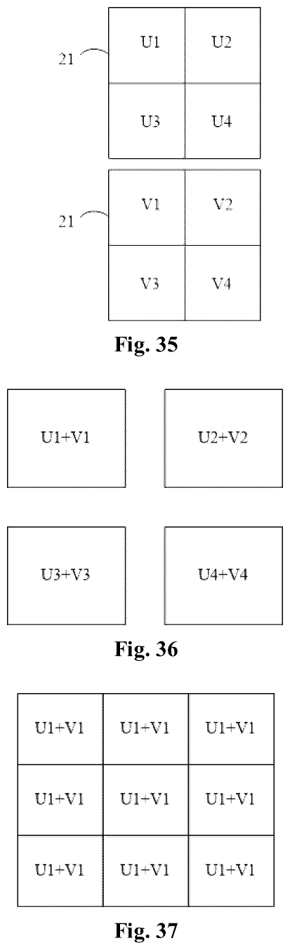

Referring to FIG. 33 to FIG. 38, FIG. 33 to FIG. 38 are schematic views of a principle for transferring a first light-emitting element according to embodiments of the present application; in the method for manufacturing the display panel, the method for transferring the first light-emitting element includes the following step.

First, as shown in FIG. 33, after the manufacturing of the first device wafers 20 which include the first light-emitting elements is completed, the first device wafers 20 of the same batch may be fully tested by the PL testing device to determine the dominant wavelength distributions of the first device wafers 20. In this step, at least the rectangular effective regions 21 are tested to obtain the dominant wavelength distributions of the rectangular active regions 21 in the first device wafers 20.

Then, as shown in FIG. 34, the grouping may be automatically performed by image processing software in the computer to determine two first device wafers 20 which have complementary dominant wavelength distributions.

As shown in FIG. 25, the first transfer is performed to transfer the rectangular effective regions 21 in two first device wafers 20 to the first carrier base plate as a whole.

One of the first device wafers 20 is set to have four blocks which are the first block to the fourth block in sequence. One of the blocks has a plurality of first light-emitting elements. For two first device wafers 20 in the wafer complementary group, the plurality of first light-emitting elements which correspond to the four blocks in one of the first device wafers 20 are U1, U2, U3 and U4, respectively, and the plurality of first light-emitting elements which correspond to the four blocks in the other of the first device wafers 20 are V1, V2, V3 and V4, respectively. U1 and V1 correspond to the first block, U2 and V2 correspond to the second block, U3 and V3 correspond to the third block, and U4 and V4 correspond to the fourth block.

As shown in FIG. 36, the second transfer is performed to transfer the first light-emitting elements on the first carrier base plate to the second carrier base plate based on the arrangement of the light-emitting elements of colors in the display panel. In the process of this transfer, the plurality of first light-emitting elements which correspond to the same blocks in two first device wafers are transferred to the second carrier base plate based on the arrangement of the above two types of first light-emitting elements which have different dominant wavelengths. As shown in the g-th block, Ug and Vg which have different dominant wavelengths are transferred to the same second carrier base plate based on the arrangement of the above two types of first light-emitting elements which have different dominant wavelengths, and the plurality of first light-emitting elements in different blocks are transferred to different second carrier base plates. As shown in FIG. 36, the first block to the fourth block correspond to one second carrier base plate, and there are four second carrier base plates in total, and g is a positive integer not greater than 4.

Taking the second carrier base plate to which U1 and V1 are transferred as an example, as shown in FIG. 37, a plurality of blocks one of which includes U1 and V1 may be formed on the second carrier base plate based on the two types of first light-emitting elements which have different dominant wavelengths. One of the rectangular boxes in FIG. 37 represents one block. The plurality of blocks in the second carrier base plate are not limited to three rows and three columns of blocks shown in FIG. 37, which may be adjusted based on the design parameters of the display panel. In the second carrier base plate, one of the plurality of blocks is formed by arranging U1 and V1; as shown in FIG. 3, one of U1 and V1 may be set to be B1, and the other may be set to be B2.

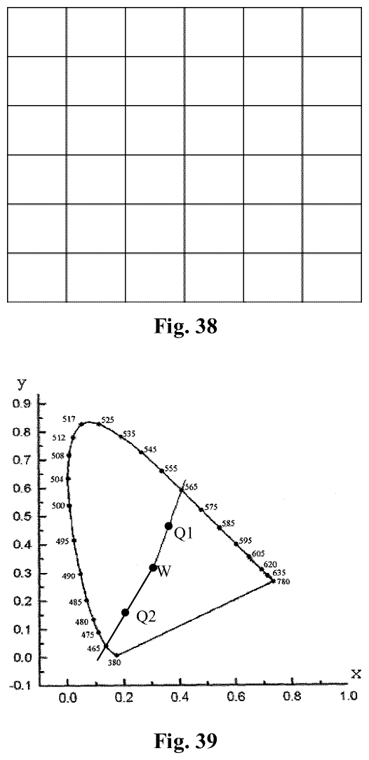

Finally, as shown in FIG. 38, the plurality of light-emitting elements in the plurality of blocks in FIG. 37 are transferred to the array base plate a plurality of times. The plurality of light-emitting elements in the same block may be transferred in different steps. In FIG. 38, one of the rectangular boxes may represent one first light-emitting element.

In the embodiments of the present application, the dominant wavelengths of the plurality of light-emitting elements may be directly measured and obtained by a photometer, and the output dominant wavelengths may be directly tested by a colorimeter.

FIG. 39 is a schematic view of a calculation principle of a dominant wavelength of a light-emitting element according to embodiments of the present application. For a given light-emitting element, the color coordinate of light which is emitted by the given light-emitting element in the CI3.1931 chromaticity diagram is determined, and the wavelength which correspond to the intersection point of the line connecting the standard white light color coordinate W to the color coordinate and the boundary of the chromaticity diagram is the dominant wavelength of the light-emitting element.

As shown in FIG. 39, if the color coordinate of light which is emitted by one light-emitting element is the point Q1, the wavelength 565 nm which corresponds to the intersection point of the line connecting W to Q1 and the boundary of the chromaticity diagram is the dominant wavelength of the light-emitting element; if the color coordinate of light which is emitted by one light-emitting element is the point Q2, the wavelength 465 nm which corresponds to the intersection point of the line connecting W to Q2 and the boundary of the chromaticity diagram is the dominant wavelength of the light-emitting element.

In the specification of the present application, the embodiments are described in a progressive or coordinate manner, or a progressive and coordinate manner, and each of the embodiments focuses on differences from other embodiments, and the same and similar parts of the embodiments may be referred to each other. The embodiments of the present application may be combined without conflict.

It should be noted that in the description of the present application, it should be understood that the description of the drawings and the embodiments are illustrative but not restrictive. The same reference numerals throughout the embodiments of the specification represent the same structures. In addition, for the sake of understanding and ease of description, the thickness of some layers, films, panels, regions, and the like may be enlarged in the drawings. At the same time, it may be understood that under a condition that an element such as a layer, film, region or base plate is referred to as “on” another element, the element may be directly on another element or intervening elements may be provided therebetween. In addition, “on” means positioning an element on or under another element, but does not essentially mean positioning on the upper side of another element according to the direction of gravity.

The terms “upper”, “lower”, “top”, “bottom”, “inner”, “outer”, and the like indicate orientations or positional relationships based on the orientations or the positional relationships shown in the drawings, which are merely to facilitate and simplify the description of the present application, rather than to indicate or imply that the referenced apparatuses or elements must have a particular orientation, or be constructed and operated in a particular orientation. Accordingly, no limitations are intended to the present application. Under a condition that a component is considered to be “connected” to another component, it may be a component which is directly connected to another component or may be an intervening component which is provided therebetween.

It should be noted that, in the present application, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that an article or device including a series of elements includes not only those elements, but also other elements that are not explicitly listed or elements inherent to such an article or device. Without more constraints, the elements following an expression “comprise/include . . . ” do not exclude the existence of additional identical elements in the article or device that includes the elements.

Through the above description of the disclosed embodiments, those skilled in the art implement or use the present application. Various modifications to these embodiments will be apparent to those skilled in the art, and the general principles defined herein may be implemented in other embodiments without departing from the gist or scope of the present application. Accordingly, the present application will not be limited to the embodiments shown herein, but is intended to fit the widest scope consistent with the principles and novel features disclosed herein.

What is claimed is:

1. A display panel comprising:
a display layer comprising a plurality of first light-emitting units which are arranged in an array; one of the plurality of first light-emitting units comprising at least one first light-emitting element which emits light of a first color, wherein
dominant wavelengths of the plurality of first light-emitting units satisfy:
$$\vert {D}_{1} - {D}_{2} \vert > 0 ,$$
where D₁ represents a first difference between the dominant wavelengths of the first light-emitting elements in two of the plurality of first light-emitting units which are adjacent to each other along a first direction, and the first direction comprises at least one of a row direction or a column direction of the array where the plurality of first light-emitting units are located; and
D₂ represents a second difference between the dominant wavelengths of the first light-emitting elements in two of the plurality of first light-emitting units which are adjacent to each other along a second direction, an angle between the second direction and the first direction is greater than 0° and less than 90°.

2. The display panel according to claim 1, wherein one of the plurality of first light-emitting units comprises one of the first light-emitting elements; or
wherein one of the plurality of first light-emitting units comprises a number p of the first light-emitting elements, where p is a positive integer greater than 1,
the dominant wavelengths of the plurality of first light-emitting units satisfy D₁−D₂>0, and a difference between the dominant wavelengths of two of the first light-emitting elements in a same one of the plurality of first light-emitting units is not greater than a first threshold which is less than or equal to D₂.

3. The display panel according to claim 1,
wherein the dominant wavelengths of the plurality of first light-emitting units satisfy D₁−D₂>0; and
wherein in the array where the plurality of first light-emitting units are located,
along both the row direction and the column direction, the plurality of first light-emitting units which have a first dominant wavelength and the plurality of first light-emitting units which have a second dominant wavelength are alternately arranged; and
a difference between the first dominant wavelength and the second dominant wavelength is not less than a second threshold which is greater than or equal to D₁.

4. The display panel according to claim 3, wherein the plurality of first light-emitting units comprise a first main light-emitting unit, a sum of absolute values of differences between the dominant wavelength of the first main light-emitting unit and the dominant wavelengths of four of the plurality of first light-emitting units which are adjacent to the first main light-emitting unit along the first direction is a first sum value, and a sum of absolute values of differences between the dominant wavelength of the first main light-emitting unit and dominant wavelengths of four of the plurality of first light-emitting units which are adjacent to the first main light-emitting unit along the second direction is a second sum value; and
the first sum value is greater than twice the second sum value.

5. The display panel according to claim 3, wherein the plurality of first light-emitting units comprise a first main light-emitting unit, a sum of absolute values of differences between the dominant wavelength of the first main light-emitting unit and the dominant wavelengths of four of the plurality of first light-emitting units which are adjacent to the first main light-emitting unit along the first direction is a first sum value, and a sum of absolute values of differences between the dominant wavelength of the first main light-emitting unit and dominant wavelengths of four of the plurality of first light-emitting units which are adjacent to the first main light-emitting unit along the second direction is a second sum value; and
the first sum value is less than twice the second sum value.

6. The display panel according to claim 3, wherein one of the plurality of first light-emitting units has the first light-emitting elements which are arranged in m rows and n columns, where
m and n are both positive integers not greater than 2.

7. The display panel according to claim 1, wherein the display layer has c types of the plurality of first light-emitting units which have dominant wavelengths different from each other, where c is a positive integer greater than 1; and
the display layer is evenly divided into a plurality of sub-display regions which are arranged in an array; and
in a same one of the plurality of sub-display regions, a number of the plurality of first light-emitting units is not less than c, and the dominant wavelengths of at least c of the plurality of first light-emitting units are different from each other.

8. The display panel according to claim 7, wherein, along the first direction, a difference between the dominant wavelengths of any two of the plurality of first light-emitting units which are adjacent to each other is the first difference.

9. The display panel according to claim 8, wherein one of the plurality of first light-emitting units has the first light-emitting elements which are arranged in m rows and n columns, where m and n are both positive integers;
under a condition that c≥2, m=n=1, or under a condition that c=2, at least one of m or n is greater than 1.

10. The display panel according to claim 7, wherein, in the same one of the plurality of sub-display regions, along the first direction, the dominant wavelengths of c consecutive ones of the plurality of first light-emitting units are different from each other.

11. The display panel according to claim 7, wherein, in the same one of the plurality of sub-display regions, along the first direction, a difference between the dominant wavelengths of two of the plurality of first light-emitting units which are adjacent to each other is the first difference, and along the second direction, a difference between the dominant wavelengths of two of the plurality of first light-emitting units which are adjacent to each other is the second difference;
where
in the plurality of first light-emitting units in a same one of rows, two types of the plurality of first light-emitting units which have the dominant wavelengths different from each other are alternately arranged in sequence; in the plurality of first light-emitting units in a same one of columns, two types of the plurality of first light-emitting units which have the dominant wavelengths different from each other are alternately arranged in sequence; or
along one of the row direction and the column direction, two types of the plurality of first light-emitting units which have the dominant wavelengths different from each other are alternately arranged in sequence; along the other of the row direction and the column direction, the dominant wavelengths of c consecutive ones of the plurality of first light-emitting units are different from each other.

12. The display panel according to claim 7, wherein, under a condition that c>3, in the same one of the plurality of sub-display regions, along the first direction, the dominant wavelengths of at most c consecutive ones of the plurality of first light-emitting units are different from each other; in the plurality of first light-emitting units in the same one of columns, three types of the plurality of first light-emitting units which have the dominant wavelengths different from each other are alternately arranged; and in the plurality of first light-emitting units in the same one of rows, three types of the plurality of first light-emitting units which have the dominant wavelengths different from each other are alternately arranged.

13. The display panel according to claim 1, wherein the display layer further comprises a plurality of second light-emitting units which are arranged in an array, and one of the plurality of second light-emitting units comprises at least one second light-emitting element which emits light of a second color, wherein
dominant wavelengths of the plurality of second light-emitting units satisfy:
$$\vert {D}_{3} - {D}_{4} \vert > 0 ,$$
where D₃ represents a third difference between the dominant wavelengths of the second light-emitting elements in two of the plurality of second light-emitting units which are adjacent to each other along a third direction, the third direction comprises at least one of a row direction or a column direction of the array where the plurality of second light-emitting units are located; and
D₄ represents a fourth difference between the dominant wavelengths of the second light-emitting elements in two of the plurality of second light-emitting units which are adjacent to each other along a fourth direction, an angle between the fourth direction and the third direction is greater than 0° and less than 90°.

14. The display panel according to claim 13, wherein one of the plurality of second light-emitting units comprises one of the second light-emitting elements; or
wherein one of the plurality of second light-emitting units comprises a number of q of the second light-emitting elements, where q is a positive integer greater than 1,
the dominant wavelengths of the plurality of second light-emitting units satisfy D₃−D₄>0, and a difference between the dominant wavelengths of two of the plurality of second light-emitting elements in a same one of the plurality of second light-emitting units is not greater than a third threshold which is less than or equal to D₄.

15. The display panel of claim 13, wherein
the first difference is greater than the second difference, and the third difference is greater than the fourth difference;
the display layer comprises c types of the plurality of second light-emitting units which have the dominant wavelengths different from each other, where c is a positive integer greater than 1; and
the display layer comprises a plurality of pixel units, one of the plurality of pixel units comprises the first light-emitting element which has one of the dominant wavelengths and the second light-emitting element which has one of the dominant wavelengths; and the plurality of pixel units comprise first pixel units and second pixel units, the dominant wavelength of the first light-emitting element in one of the first pixel units is greater than the dominant wavelength of the first light-emitting element in one of the second pixel units, and the dominant wavelength of the second light-emitting element in one of the first pixel units is greater than the dominant wavelength of the second light-emitting element in one of the second pixel units.

16. The display panel according to claim 1, wherein the first light-emitting elements are connected to pixel circuits for controlling the connected first light-emitting elements to display an image;
the display layer comprises c types of the first light-emitting elements which have dominant wavelengths different from each other, where c is a positive integer greater than 1; and
under a condition that a same one of gray scales is displayed, in the c types of the first light-emitting elements which have the dominant wavelengths different from each other, data voltages which are provided by at least two types of the pixel circuits are different from each other.

17. An electronic device comprising a display panel, the display panel comprising:
a display layer comprising a plurality of first light-emitting units which are arranged in an array; one of the plurality of first light-emitting units comprising at least one first light-emitting element which emits light of a first color, wherein
dominant wavelengths of the plurality of first light-emitting units satisfy:
$$\vert {D}_{1} - {D}_{2} \vert > 0 ,$$
where D₁ represents a first difference between the dominant wavelengths of the first light-emitting elements in two of the plurality of first light-emitting units which are adjacent to each other along a first direction, and the first direction comprises at least one of a row direction or a column direction of the array where the plurality of first light-emitting units are located; and
D₂ represents a second difference between the dominant wavelengths of the first light-emitting elements in two of the plurality of first light-emitting units which are adjacent to each other along a second direction, an angle between the second direction and the first direction is greater than 0° and less than 90°.

18. A method for manufacturing the display panel of claim 1, comprising:
manufacturing first device wafers;
testing the first device wafers to acquire wavelength distributions of a plurality of first light-emitting elements in the first device wafers;
determining the wavelength distributions based on dominant wavelengths of a plurality of test regions;
determining wafer complementary groups; and
welding and fixing the plurality of first light-emitting elements which are arranged in an array on an array base plate, and sourcing the plurality of first light-emitting elements which are welded and fixed on the array base plate to a same one of the wafer complementary groups;
wherein one of the first device wafers comprises the plurality of first light-emitting elements which emit light of a first color,
one of the first device wafers comprises the plurality of test regions, one of the plurality of test regions comprises at least one of the plurality of first light-emitting elements,
one of the wafer complementary groups comprises c of the first device wafers which have complementary wavelength distributions,
the array base plate has a plurality of first light-emitting units which are arranged in an array; and one of the plurality of first light-emitting units comprises at least one first light-emitting element which emits light of a first color, wherein
dominant wavelengths of the plurality of first light-emitting units satisfy:
$$\vert {D}_{1} - {D}_{2} \vert > 0 ,$$
where D₁ represents a first difference between the dominant wavelengths of the first light-emitting elements in two of the plurality of first light-emitting units which are adjacent to each other along a first direction, and the first direction comprises at least one of a row direction or a column direction of the array where the plurality of first light-emitting units are located; and
D₂ represents a second difference between the dominant wavelengths of the first light-emitting elements in two of the plurality of first light-emitting units which are adjacent to each other along a second direction, an angle between the second direction and the first direction is greater than 0° and less than 90°.

19. The method according to claim 18, wherein the testing the first device wafers comprises:
dividing a rectangular effective region of one of the first device wafers into M*N of the test regions; and
testing dominant wavelengths of the test regions to determine the wavelength distributions of the plurality of first light-emitting elements in the first device wafers;
wherein M and N are both positive integers greater than 1.

20. The method according to claim 19, wherein the determining wafer complementary groups comprises:
calculating average values Hₖ of dominant wavelengths of the k-th ones of the test regions in c of the first device wafers;
forming a dominant wavelength matrix of M rows and N columns using the average values of H₁ to Hₚ which correspond to the M*N of the test regions;
calculating a range and a standard deviation of the dominant wavelength matrix; and
determining, under a condition that the range is not greater than a first calibration value and the standard deviation is not greater than a second calibration value, wavelength distributions of the c of the first device wafers are complementary; where
in a same one of the first device wafers, the M*N of the test regions are the first one to the P-th one of the test regions, respectively, P=M*N,
k is a positive integer not greater than P,
the first calibration value is not greater than 4 nm, and the second calibration value is not greater than 0.6 nm.
